(19) United States
(12) Patent Application Publication
(10) Pub. No.: US 2025/0380573 A1
(43) Pub. Date: Dec. 11, 2025

(54) DISPLAY DEVICE AND METHOD OF MANUFACTURING THE SAME

(71) Applicant: Samsung Display Co., Ltd., Yongin-si (KR)

(72) Inventors: KANGSEOB JEONG, Yongin-si (KR); TAEHOON KIM, Yongin-si (KR); JAE CHEOL PARK, Yongin-si (KR); DANBI YANG, Yongin-si (KR)

(21) Appl. No.: 18/990,624

(22) Filed: Dec. 20, 2024

(30) Foreign Application Priority Data
Jun. 10, 2024 (KR) 10-2024-0075028

(51) Int. Cl. H10K 59/122; H10K 59/12; H10K 59/38; H10K 59/80; H10K 59/88; H10K 102/00

(52) U.S. Cl. CPC H10K 59/122; H10K 59/1201; H10K 59/38; H10K 59/88; H10K 59/878; H10K 59/8792; H10K 2102/331

(57) ABSTRACT

A method of manufacturing a display device, the method including providing a pixel defining film on a substrate, defining an opening, overlapping a light emitting area, in the pixel defining film, applying an ink to each of a plurality of drop points on an upper surface of the pixel defining film overlapping a non-light emitting area around the light emitting area, forming a barrier layer by curing the ink, and placing a light emitting element in the opening.

### CROSS-REFERENCE TO RELATED APPLICATION

The present application claims priority to and the benefit of Korean Patent Application No. 10-2024-0075028, filed on Jun. 10, 2024, in the Korean Intellectual Property Office, the entire disclosure of which is incorporated herein by reference.

### BACKGROUND

Embodiments of the present disclosure described herein relate to a display device and a method of manufacturing the display device.

Electronic devices, such as smartphones, digital cameras, laptop computers, navigation systems, and/or smart televisions, include display devices for presenting (displaying) images to users. The display device generates an image and provides the generated image to the user through a display screen.

Recently, display devices including light converting layers have been developed to improve color purity. These light converting layers are arranged on pixels and convert light generated by the pixels into light of a different wavelength. Each of the light converting layers is arranged (positioned) to overlap a corresponding pixel selected from among the pixels. The light converting layers include quantum dots that alter (convert) the wavelength of the light.

When the lights generated by the pixels are directed (provided) to the corresponding light converting layers, respectively, a color matching rate is improved. However, if the lights generated by the pixels are directed (provided) to other (adjacent) light converting layers (e.g., layers adjacent to the corresponding light converting layers), the color matching rate may decrease.

### SUMMARY

Aspects of embodiments of the present disclosure are directed toward a display device with (having) an improved color matching rate and reduced manufacturing costs, as well as a method of manufacturing the display device. Additional aspects will be set forth in part in the description which follows and, in part, will be apparent from the description, or may be learned by practice of the presented embodiments of the disclosure.

According to one or more embodiments, a method of manufacturing a display device includes providing a pixel defining film on a substrate, defining an opening, overlapping a light emitting area, in the pixel defining film, providing an ink to each of a plurality of drop points on an upper surface of the pixel defining film overlapping a non-light emitting area around the light emitting area, forming a barrier layer by curing the ink, and providing a light emitting element to the opening.

According to one or more embodiments, a display device includes a substrate including a light emitting area and a non-light emitting area around the light emitting area, a pixel defining film which is arranged on the substrate, in which an opening overlapping the light emitting area is defined, and which overlaps the non-light emitting area, a barrier layer arranged on the pixel defining film, and a light emitting element arranged on the opening, where an upper surface of the pixel defining film has liquid repellency, and a cross section of the barrier layer cut in a direction intersecting an extension direction of the barrier layer has an upwardly convex curved surface.

According to one or more embodiments, a method of manufacturing a display device includes providing a pixel defining film on a substrate, defining an opening, overlapping a light emitting area, in the pixel defining film, providing (applying) an ink to each of a plurality of drop points defined on an upper surface of the pixel defining film overlapping a non-light emitting area around the light emitting area, forming a barrier layer by curing the ink, providing (placing) a light emitting element to (in) the opening, and providing a quantum dot layer on the light emitting element, where the ink provided (applied) to each of the plurality of drop points has a smaller thickness and is spread further (longer) along a side of the light emitting area as surface energy of the upper surface of the pixel defining film increases (becomes greater).

### BRIEF DESCRIPTION OF THE DRAWINGS

The above and other objects and features of the present disclosure will become apparent by describing in more detail embodiments thereof with reference to the accompanying drawings.

FIG. 1 is a perspective view of a display device, according to one or more embodiments of the present disclosure.

FIG. 2 is an exploded perspective view of the display device illustrated in FIG. 1.

FIG. 3 is a view illustrating a cross section of a display module illustrated in FIG. 2.

FIG. 4 is a plan view of a display panel illustrated in FIG. 3.

FIG. 5 is a view illustrating a cross section of any one pixel illustrated in FIG. 4.

FIG. 6 is a plan view of light emitting elements and a barrier layer arranged in a portion of a display area of the display panel illustrated in FIG. 4.

FIG. 7 is a cross-sectional view of a display module corresponding to line I-I′ illustrated in FIG. 6.

FIG. 8 is a cross-sectional view along line II-II′ illustrated in FIG. 6.

FIG. 9 is a cross-sectional view along line III-III′ illustrated in FIG. 6.

FIG. 10 is a cross-sectional view of line IV-IV′ illustrated in FIG. 6.

FIG. 11 is a cross-sectional view along line V-V′ illustrated in FIG. 6.

FIG. 12 is a view illustrating another configuration of a first barrier layer corresponding to the cross-sectional view along line II-II′ illustrated in FIG. 6.

FIG. 13 is a view illustrating another configuration of a second barrier layer corresponding to the cross-sectional view along line IV-IV′ illustrated in FIG. 6.

FIG. 14 is a view illustrating another configuration of the first barrier layer corresponding to the cross-sectional view along line II-II′ illustrated in FIG. 6.

FIG. 15 is a view illustrating another configuration of the first barrier layer corresponding to the cross-sectional view along line III-III′ illustrated in FIG. 6.

FIG. 16 is a view illustrating another configuration of the second barrier layer corresponding to the cross-sectional view along line IV-IV′ illustrated in FIG. 6.

FIG. 17 is a view illustrating another configuration of the second barrier layer corresponding to the cross-sectional view along line V-V′ illustrated in FIG. 6.

FIG. 18 is a graph depicting a height of ink provided on an upper surface of a pixel defining film, according to surface energy of the upper surface of the pixel defining film.

FIG. 19 is a table illustrating a spread length of the ink provided on the upper surface of the pixel defining film, according to the surface energy of the upper surface of the pixel defining film.

FIGS. 20A-20H are views for describing a method of manufacturing a display device, according to one or more embodiments of the present disclosure.

FIG. 21 is a view illustrating a plurality of drop points of ink in the method of manufacturing a display device when the upper surface of the pixel defining film has first surface energy.

FIGS. 22A-22D are views for describing a method of forming the first and second barrier layers illustrated in the cross sections of FIGS. 9 and 11 when the upper surface of the pixel defining film has the first surface energy.

FIGS. 23A-23D are views illustrating a method of forming the first and second barrier layers illustrated in the cross sections of FIGS. 14 and 16.

FIG. 24 is a view illustrating the plurality of drop points of ink in the method of manufacturing a display device when the upper surface of the pixel defining film has second surface energy.

FIGS. 25A-25D are views for describing a method of forming the first and second barrier layers illustrated in the cross sections of FIGS. 15 and 17 when the upper surface of the pixel defining film has the second surface energy.

FIGS. 26A and 26B are views each illustrating a configuration of the barrier layer, according to one or more embodiments of the present disclosure.

FIG. 27 is a view illustrating a configuration of the barrier layer, according to one or more embodiments of the present disclosure.

FIG. 28 is a view illustrating a configuration of the barrier layer, according to one or more embodiments of the present disclosure.

### DETAILED DESCRIPTION

In the present specification, the expression that a first component (or an area, a layer, a part, a portion, and/or the like.) is “arranged on”, “connected with” or “coupled to” a second component refers to that the first component is directly arranged on/connected with/coupled to the second component or refers to that a third component is interposed therebetween.

The same reference numerals refer to the same components. Furthermore, in the drawings, the thickness, the ratio, and the dimension of components are exaggerated for effective description of technical contents.

The term “and/or” includes all combinations of one or more components that may be defined by associated configurations.

Although the terms “first”, “second”, and/or the like. may be utilized to describe one or more suitable components, the components should not be limited by the terms. The terms are only utilized to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, when an element or layer is referred to as being “directly on,” “directly connected to”, “directly coupled to”, or “immediately adjacent to” another element or layer, there are no intervening elements or layers present.

Furthermore, the terms “under”, “beneath”, “on”, “above”, and/or the like. are utilized to describe a relationship between components illustrated in the drawings. The terms that are relative in concept are described based on a direction illustrated in drawings.

Unless otherwise defined, all terms (including technical terms and scientific terms) utilized in the specification have the same meaning as commonly understood by those skilled in the art to which the present disclosure belongs. Furthermore, terms such as terms defined in the dictionaries commonly utilized should be interpreted as having a meaning consistent with the meaning in the context of the related technology and should not be interpreted in ideal or overly formal meanings unless explicitly defined herein.

It will be understood that the terms “include”, “comprise”, “have”, and/or the like specify the presence of features, numbers, steps, operations, elements, or components, described in the specification, and/or a (e.g., any suitable) combination thereof, and do not exclude in advance the presence or additional possibility of one or more other features, numbers, steps, operations, elements, or components and/or a (e.g., any suitable) combination thereof.

Hereinafter, one or more embodiments of the present disclosure will be described with reference to the accompanying drawings.

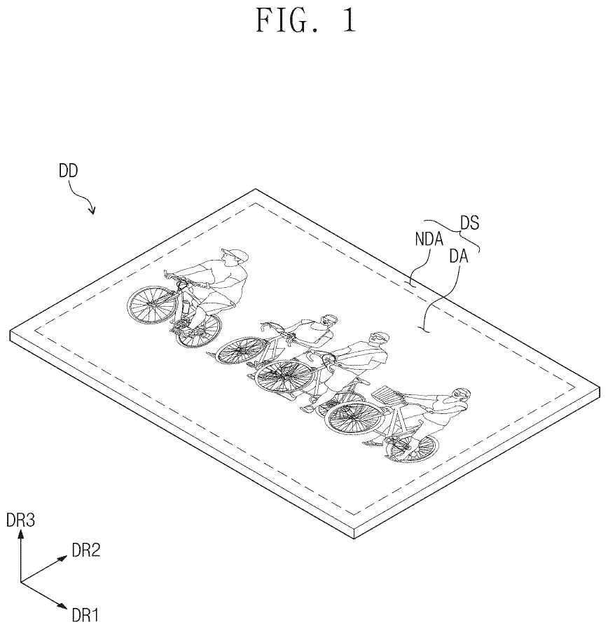

FIG. 1 is a perspective view of a display device, according to one or more embodiments of the present disclosure.

Referring to FIG. 1, a display device DD may have a rectangular shape having long sides extending in a first direction DR1 and short sides extending in a second direction DR2 crossing (e.g., intersecting) the first direction DR1. However, the present disclosure is not limited thereto, and the display device DD may have one or more suitable shapes, such as a circular shape and/or polygonal shapes.

Hereinafter, a direction substantially normal (e.g., perpendicular) to a plane defined by the first direction DR1 and the second direction DR2 is defined as a third direction DR3. Furthermore, in the specification, the wording “if (e.g., when) viewed on a plane” may be defined as a state of being viewed from the third direction DR3 (in a plan view).

An upper surface of the display device DD may be defined as a display surface DS, and may have the plane defined by the first direction DR1 and the second direction DR2. An image generated by the display device DD may be provided to a user through the display surface DS.

The display surface DS may include a display area DA and a non-display area NDA around the display area DA. The display area DA displays an image, and the non-display area NDA does not display the image. The non-display area NDA may be around (e.g., surround) the display area DA, and may define an edge of a display module DM printed in a set or predetermined color.

The display device DD may be utilized for large-sized electronic devices such as televisions, monitors, or external billboards. Furthermore, the display device DD may be utilized for small or medium-sized electronic devices such as a personal computer (PC), a laptop, a personal digital terminal, a vehicle navigation system, a game console, a smart phone, a tablet PC, or a camera. However, these are merely presented as one or more embodiments and may be utilized for other electronic devices as long as the other electronic devices do not deviate from the concept of the present disclosure.

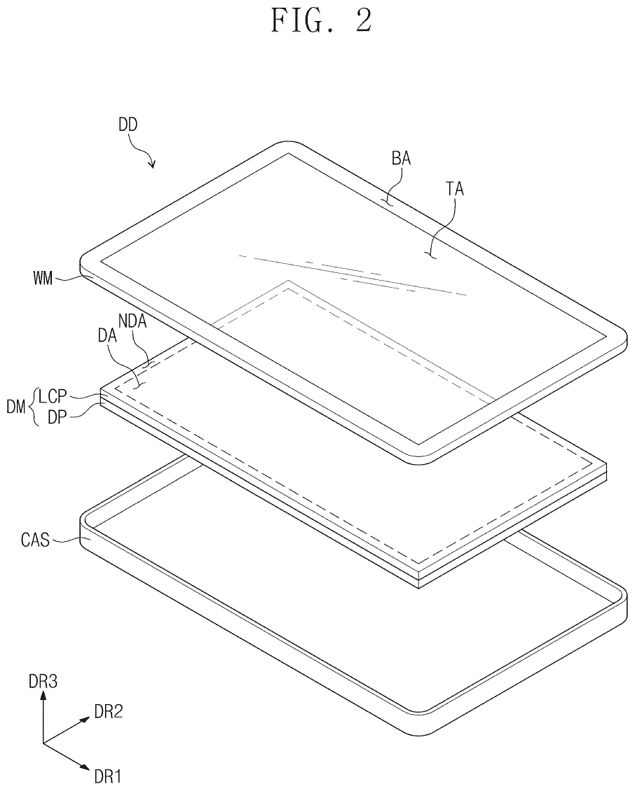

FIG. 2 is an exploded perspective view of the display device illustrated in FIG. 1.

Referring to FIG. 2, the display device DD may include a window WM, the display module DM, and a case CAS. The window WM, the display module DM, and the case CAS may have a rectangular shape having long sides extending in the first direction DR1 and short sides extending in the second direction DR2.

The window WM may be arranged on the display module DM. The window WM may have optically transparent properties. For example, the window WM may include glass, transparent plastic, and/or the like. The window WM may protect the display module DM from external impacts and scratches. A front surface of the window WM may correspond to the display surface DS of the display device DD.

A front surface of the window WM may include a transmissive area TA and a bezel area BA around the transmissive area TA. The transmissive area TA may be to transmit a light. The bezel area BA may be around (e.g., surround) the transmissive area TA and may be printed in a set or predetermined color to shield a light. The transmissive area TA may overlap the display area DA, and the bezel area BA may overlap the non-display area NDA. In the specification, the wording “overlap” may be defined as a state in which components overlap each other if (e.g., when) viewed on a plane (e.g., in a plan view).

The display module DM may be arranged between the window WM and the case CAS. The display module DM may include the display area DA and the non-display area NDA around the display area DA. The non-display area NDA may be around (e.g., surround) the display area DA. The display area DA and the non-display area NDA of the display module DM may respectively correspond to the display area DA and the non-display area NDA illustrated in FIG. 1.

The display area DA may generate an image, and the non-display area NDA may not generate an image (e.g., the non-display area may not be configured to generate an image). The image generated in the display area DA may be provided to an external user through the transmissive area TA.

The display module DM may include a display panel DP and a light converting unit LCP arranged on the display panel DP. In one or more embodiments, like the display module DM (e.g., the display panel DP may have a configuration similar to the display module DM), the display panel DP may include the display area DA and the non-display area NDA arranged around the display area DA and surrounding the display area DA. An image may be generated in the display area DA of the display panel DP. The non-display area NDA may not be exposed to the outside by the bezel area BA. For example, the bezel area BA may be arranged on (e.g., cover) the surface of the non-display area NDA, so that the non-display area NDA is not exposed.

In one or more embodiments, the display panel DP may be a light emitting display panel. For example, the display panel DP may be an organic light emitting display panel and/or an inorganic light emitting display panel. A light emitting layer of the organic light emitting display panel may include an organic light emitting material. A light emitting layer of the inorganic light emitting display panel may include a quantum dot and/or a quantum rod. Hereinafter, the display panel DP will be described as the organic light emitting display panel.

The light converting unit LCP may receive a light generated by the display panel DP and convert a color of the received light. Furthermore, the light converting unit LCP may decrease a reflectance of an external light. This configuration will be described in more detail later.

The case CAS may be arranged under the display module DM and accommodate the display module DM. For example, the shape of the case CAS may correspond to the shape of the display module DM, so that the display module DM may be placed in the case CAS. The case CAS may be to absorb an external impact and block external foreign substances and moisture, thereby protecting the display module DM.

In one or more embodiments, the display device DD may further include an input sensing unit arranged between the display panel DP and the light converting unit LCP. The input sensing unit may include a plurality of sensing units for sensing an external input. The sensing units may sense an external input in a capacitance method.

In one or more embodiments, the input sensing unit may be directly manufactured on the display panel DP when the display panel DP is manufactured. However, the present disclosure is not limited thereto, and the input sensing unit may be manufactured as a separate panel from the display panel DP and may be attached to the display panel DP by an adhesive.

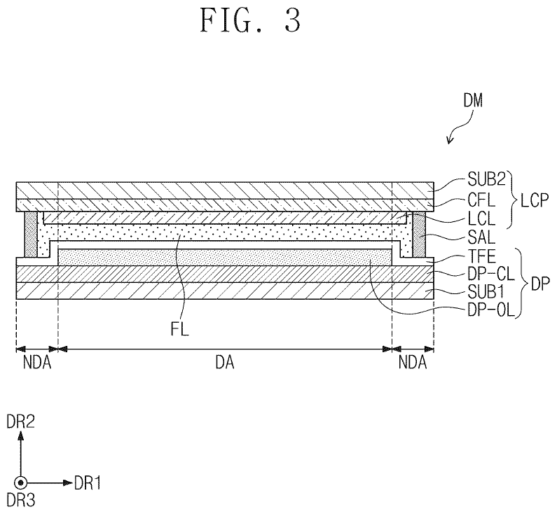

FIG. 3 is a view illustrating a cross section of a display module illustrated in FIG. 2.

FIG. 3 illustrates a cross section of the display module DM if (e.g., when) viewed in the first direction DR1.

Referring to FIG. 3, the display module DM may include the display panel DP, the light converting unit LCP, a filler FL, and/or a sealant SAL. The light converting unit LCP may be arranged on the display panel DP, and the filler FL and the sealant SAL may be arranged between the light converting unit LCP and the display panel DP.

The sealant SAL may overlap the non-display area NDA and may be arranged between the light converting unit LCP and the display panel DP. The light converting unit LCP and the display panel DP may be connected to (e.g., bonded to) each other by the sealant SAL. The sealant SAL may contain an ultraviolet curable material.

The filler FL may overlap the display area DA and may be arranged between the light converting unit LCP and the display panel DP. The filler FL may be extended toward the non-display area NDA and may be in contact with the sealant SAL. The filler FL may include silicone, epoxy, and/or an acrylic-based thermosetting material.

The display panel DP may include a first substrate SUB1, a circuit element layer DP-CL, a display element layer DP-OL, and/or a thin film encapsulation layer TFE. The light converting unit LCP may include a second substrate SUB2, a color filter layer CFL, and/or a light converting layer LCL.

The second substrate SUB2 may be arranged on the first substrate SUB1 and face the first substrate SUB1. The circuit element layer DP-CL, the display element layer DP-OL, the thin film encapsulation layer TFE, the color filter layer CFL, the light converting layer LCL, the filler FL, and/or the sealant SAL may be arranged between the first substrate SUB1 and the second substrate SUB2.

The first substrate SUB1 and the second substrate SUB2 may (each each) include glass and/or a flexible plastic material such as polyimide (PI). If (e.g., when) viewed on a plane (e.g., in a plan view), the first substrate SUB1 may include the display area DA and the non-display area NDA around the display area DA, like the display panel DP (e.g., the first substrate SUB1 may have a configuration similar to the display panel DP shown in FIG. 2, where the display panel DP may include the display area DA and the non-display area NDA around the display area DA).

The circuit element layer DP-CL may be arranged on the first substrate SUB1. The display element layer DP-OL may be arranged on the circuit element layer DP-CL. The display element layer DP-OL may be arranged on the display area DA.

A plurality of pixels may be arranged in the circuit element layer DP-CL and the display element layer DP-OL. Each of the plurality of pixels may include a transistor arranged on the circuit element layer DP-CL and a light emitting element arranged on the display element layer DP-OL and connected to the transistor. A configuration of the pixel will be described in more detail later.

The thin film encapsulation layer TFE may be arranged on the circuit element layer DP-CL to cover the display element layer DP-OL. The thin film encapsulation layer TFE may protect the plurality of pixels from moisture, oxygen, and/or external foreign substances.

The color filter layer CFL may be arranged under the second substrate SUB2. If (e.g., when) viewed on a plane (e.g., in a plan view), the color filter layer CFL may overlap the display area DA. A portion of the color filter layer CFL may overlap the non-display area NDA.

The light converting layer LCL may be arranged under the color filter layer CFL. The light converting layer LCL may overlap the display area DA if (e.g., when) viewed on a plane (e.g., in a plan view). A portion of the light converting layer LCL may overlap the non-display area NDA.

The sealant SAL may overlap the non-display area NDA and may be arranged between the first substrate SUB1 and the second substrate SUB2. The first substrate SUB1 and the second substrate SUB2 may be connected to (e.g., bonded to) each other by the sealant SAL. The sealant SAL may be arranged between the thin film encapsulation layer TFE and the color filter layer CFL. The sealant SAL may be around (e.g., surround) the light converting layer LCL. The filler FL may overlap the display area DA and may be arranged between the light converting layer LCL and the thin film encapsulation layer TFE.

A light generated in the display element layer DP-OL may be provided to the light converting layer LCL. The light converting layer LCL may convert a color of the light provided from the display element layer DP-OL. The light having the converted color may be emitted to the outside through the color filter layer CFL and the second substrate SUB2.

The color filter layer CFL may prevent or reduce reflection of an external light provided to the display panel DP from the outside. A function of the color filter layer CFL will be described in more detail later.

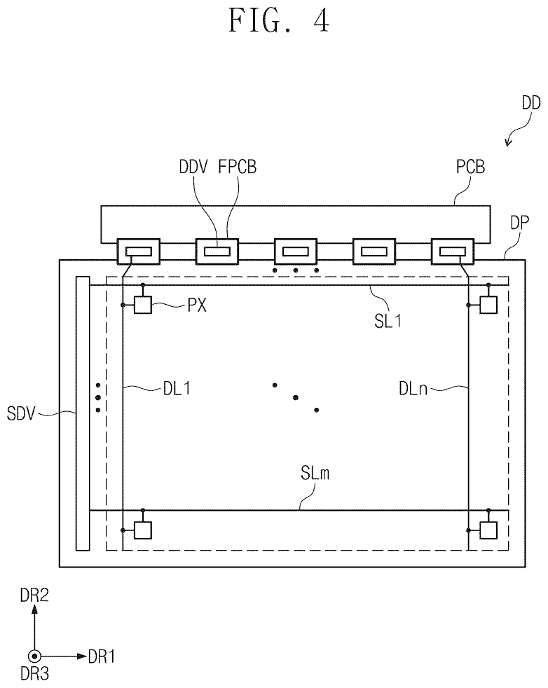

FIG. 4 is a plan view of a display panel illustrated in FIG. 3.

Referring to FIG. 4, the display device DD may include the display panel DP, a scan driver SDV, a plurality of data drivers DDV, a plurality of flexible printed circuit boards FPCB, and/or a printed circuit board PCB.

The display panel DP may have a rectangular shape having long sides extending in the first direction DR1 and short sides extending in the second direction DR2. The display panel DP may include a plurality of pixels PX, a plurality of scan lines SL1 to SLm, and a plurality of data lines DL1 to DLn, where “m” and “n” are natural numbers.

The plurality of pixels PX may be arranged in the display area DA. The scan driver SDV may be arranged in the non-display area NDA adjacent to one of the short sides of the display panel DP. The data drivers DDV may be arranged adjacent to an upper portion of the display panel DP, which is defined as one of the long sides of the display panel DP.

The printed circuit board PCB may be arranged adjacent to the upper portion of the display panel DP. The printed circuit board PCB may be connected to the display panel DP through the flexible printed circuit boards FPCB. The flexible printed circuit boards FPCB may be connected to the upper portion of the display panel DP and the printed circuit board PCB. The flexible printed circuit boards FPCB may be arranged in the first direction DR1.

The data drivers DDV may be arranged in the first direction DR1. The data drivers DDV may be manufactured in the form of an integrated circuit chip and may be mounted on the flexible printed circuit boards FPCB, respectively. The data drivers DDV may be connected to the display panel DP through the flexible printed circuit boards FPCB.

The scan lines SL1 to SLm may be extended in the first direction DR1 and may be connected to the plurality of pixels PX and the scan driver SDV. The data lines DL1 to DLn may be extended in the second direction DR2 in the display area DA and be connected to the plurality of pixels PX.

The data lines DL1 to DLn may be extended to the flexible printed circuit boards FPCB and be connected to the data drivers DDV. In FIG. 4, it is shown that two data lines DL1 and DLn are arranged on a leftmost side and a rightmost side respectively and are connected to the data drivers DDV. However, in one or more embodiments, the plurality of data lines DL1 to DLn may be connected to the data drivers DDV, respectively.

In one or more embodiments, the display device DD may include a timing controller for controlling operations of the scan driver SDV and the data drivers DDV. The timing controller may be manufactured in the form of an integrated circuit chip and arranged on (e.g., mounted on) the printed circuit board PCB.

The scan driver SDV may generate a plurality of scan signals, and the scan signals may be applied to the plurality of pixels PX through the scan lines SL1 to SLm. The data drivers DDV may generate a plurality of data voltages, and the data voltages may be applied to the plurality of pixels PX through the data lines DL1 to DLn.

The plurality of pixels PX may receive the data voltages in response to the scan signals. The plurality of pixels PX may display an image by emitting lights having luminance corresponding to the data voltages.

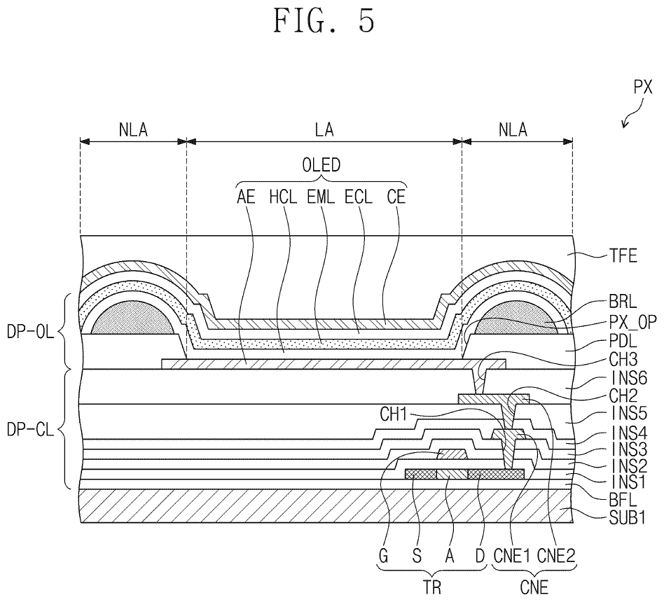

FIG. 5 is a view illustrating a cross section of any one pixel illustrated in FIG. 4.

Referring to FIG. 5, the pixel PX may include a transistor TR and a light emitting element OLED. The light emitting element OLED may include a first electrode AE (e.g., an anode), a second electrode CE (e.g., a cathode), a hole control layer HCL, an electron control layer ECL, and/or a light emitting layer EML.

The transistor TR and the light emitting element OLED may be arranged on the first substrate SUB1. In FIG. 5, one transistor TR is shown, however, in one or more embodiments, the pixel PX may include a plurality of transistors (e.g., multiple transistors TR) and at least one capacitor for driving the light emitting element OLED.

The first substrate SUB1 may include a light emitting area LA corresponding to each of the plurality of pixels PX and a non-light emitting area NLA around the light emitting area LA. The light emitting element OLED may overlap the light emitting area LA and may be arranged on the first substrate SUB1.

A buffer layer BFL may be arranged on the first substrate SUB1, and the buffer layer BFL may be an inorganic layer. A semiconductor pattern may be arranged on the buffer layer BFL. The semiconductor pattern may include polysilicon, amorphous silicon, and/or a metal oxide.

The semiconductor pattern may be doped with an N-type dopant or a P-type dopant. The semiconductor pattern may include a high-doped area and a low-doped area. Conductivity of the high-doped area is higher than conductivity of the low-doped area, and the high-doped area may substantially serve as a source electrode and a drain electrode of the transistor TR. The low-doped area may substantially correspond to an active area (or a channel) of the transistor TR.

A source area “S,” an active area “A,” and/or a drain area “D” of the transistor TR may be formed from the semiconductor pattern. A first insulating layer INS1 may be arranged on the semiconductor pattern. A gate “G” of the transistor TR may be arranged on the first insulating layer INS1. A second insulating layer INS2 may be arranged on the gate “G.” A third insulating layer INS3 may be arranged on the second insulating layer INS2.

A connection electrode CNE may include a first connection electrode CNE1 and a second connection electrode CNE2 to connect the transistor TR and the light emitting element OLED. The first connection electrode CNE1 may be arranged on the third insulating layer INS3 and may be connected to the drain area “D” through a first contact hole CH1 defined by (e.g., formed by) the first to third insulating layers INS1 to INS3.

A fourth insulating layer INS4 may be arranged on the first connection electrode CNE1. A fifth insulating layer INS5 may be arranged on the fourth insulating layer INS4. The second connection electrode CNE2 may be arranged on the fifth insulating layer INS5. The second connection electrode CNE2 may be connected to the first connection electrode CNE1 through a second contact hole CH2 defined by the fourth and fifth insulating layers INS4 and INS5.

A sixth insulating layer INS6 may be arranged on the second connection electrode CNE2. A layer from the buffer layer BFL to the sixth insulating layer INS6 may be defined as the circuit element layer DP-CL. The first insulating layer INS1 to the sixth insulating layer INS6 may be inorganic layers and/or organic layers.

The first electrode AE may be arranged on the sixth insulating layer INS6. The first electrode AE may be connected to the second connection electrode CNE2 through a third contact hole CH3 defined by (e.g., formed by) the sixth insulating layer INS6.

A pixel defining film PDL may be arranged on the first substrate SUB1, and an opening PX_OP overlapping the light emitting area LA may be defined in the pixel defining film PDL. In more detail, the pixel defining film PDL may be arranged on the first electrode AE and the sixth insulating layer INS6, and the opening PX_OP may expose a set or predetermined portion of the first electrode AE. Thus, the pixel defining film PDL may be arranged to substantially overlap the non-light emitting area NLA.

A barrier layer BRL may be arranged on the pixel defining film PDL. The barrier layer BRL may be in contact with an upper surface of the pixel defining film PDL. A more detailed configuration and function of the barrier layer BRL will be described in more detail later.

The hole control layer HCL may be arranged on the first electrode AE, the pixel defining film PDL, and the barrier layer BRL. The hole control layer HCL may be commonly arranged in the light emitting area LA and the non-light emitting area NLA. The hole control layer HCL may include a hole transport layer and/or a hole injection layer.

The light emitting layer EML may be arranged on the hole control layer HCL. The light emitting layer EML may be commonly arranged in the light emitting area LA and the non-light emitting area NLA. The light emitting layer EML may include an organic material and/or an inorganic material. The light emitting layer EML may generate a blue light.

The electron control layer ECL may be arranged on the light emitting layer EML. The electron control layer ECL may include an electron transport layer and/or an electron injection layer. The electron control layer ECL may be commonly arranged in the light emitting area LA and the non-light emitting area NLA.

The second electrode CE may be arranged on the electron control layer ECL. The second electrode CE may be commonly arranged in the plurality of pixels PX.

Portions of the first and second electrodes AE and CE overlapping the opening PX_OP, a portion of the light emitting layer EML overlapping the opening PX_OP, a portion of the hole control layer HCL overlapping the opening PX_OP, and/or a portion of the electron control layer ECL overlapping the opening PX_OP may be defined as the light emitting element OLED. A layer on which the light emitting element OLED is arranged may be defined as the display element layer DP-OL.

The thin film encapsulation layer TFE may be arranged on the second electrode CE to cover the pixel PX. The thin film encapsulation layer TFE may include two inorganic layers and an organic layer between the inorganic layers. The inorganic layers may protect the pixels (e.g., the plurality of pixels PX) from moisture and/or oxygen. The organic layer may protect the pixels from foreign substances such as dust particles.

A first voltage may be applied to the first electrode AE through the transistor TR, and a second voltage having a level lower than that of the first voltage may be applied to the second electrode CE. Holes and electrons injected into the light emitting layer EML are coupled to each other to form excitons, and as the excitons transition to a ground state, the light emitting element OLED may be to emit a light.

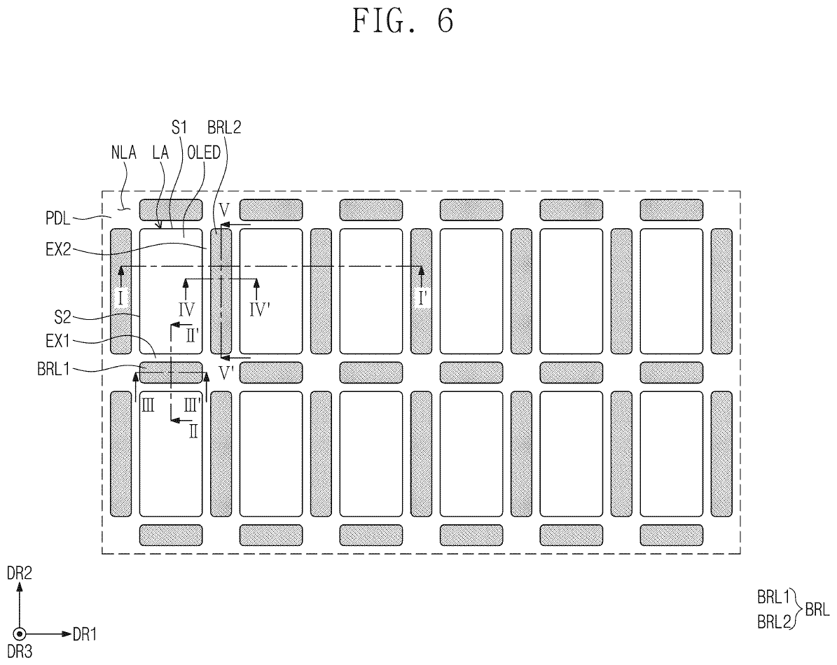

FIG. 6 is a plan view of light emitting elements and a barrier layer arranged in a portion of a display area of the display panel illustrated in FIG. 4.

FIG. 6 illustrates the light emitting elements OLED arranged in two rows and six columns. The rows may correspond to (e.g., be parallel to) the first direction DR1, and the columns may correspond to (e.g., be parallel to) the second direction DR2.

Referring to FIG. 6, the light emitting elements OLED may be arranged in the first direction DR1 and the second direction DR2. Each of the light emitting elements OLED may correspond to the light emitting element OLED illustrated in FIG. 5. A planar shape of each of the light emitting elements OLED may correspond to a planar shape of the light emitting element OLED illustrated in FIG. 5. The light emitting elements OLED may overlap the light emitting areas LA, respectively.

Each of the light emitting elements OLED may be extended longer in the second direction DR2 than in the first direction DR1. Each of the light emitting elements OLED may have a rounded corner quadrangular square shape. For example, each of the light emitting elements OLED may include two short sides extending in parallel in the first direction DR1, two long sides extending in parallel in the second direction DR2, and four rounded corners connecting the short sides and the long sides. However, the present disclosure is not limited thereto, and each of the light emitting elements OLED may have a rectangular shape.

Hereinafter, the short sides of the light emitting elements OLED are defined as first sides S1, and the long sides of the light emitting elements OLED are defined as second sides S2. A length of each of the second sides S2 may be longer than a length of each of the first sides S1.

The pixel defining film PDL may be arranged in the non-light emitting area NLA and may be arranged between the light emitting elements OLED. The pixel defining film PDL may include a plurality of extension portions EX1 and EX2 adjacent to the first and second sides S1 and S2 and extending in one direction (e.g., the first direction DR1 or the second direction DR2) parallel to the first and second sides S1 and S2.

For example, the pixel defining film PDL may include the first extension portions EX1 adjacent to the first sides S1 and extending in the first direction DR1 and the second extension portions EX2 adjacent to the second sides S2 and extending in the second direction DR2. A length of each of the second extension portions EX2 may be longer than a length of each of the first extension portions EX1.

The barrier layer BRL is provided as a plurality of barrier layers BRL, and the plurality of barrier layers BRL may be arranged adjacent to the first sides S1 and the second sides S2 of the light emitting areas LA. The plurality of barrier layers BRL may be extended along the first sides S1 and the second sides S2 of the light emitting areas LA. The plurality of barrier layers BRL may be arranged to be around (e.g., surround) the light emitting areas LA, respectively.

The plurality of barrier layers BRL may include a plurality of first barrier layers BRL1 arranged on the first extension portions EX1 and a plurality of second barrier layers BRL2 arranged on the second extension portions EX2. In the light emitting areas LA, the plurality of first barrier layers BRL1 and the plurality of second barrier layers BRL2 may be separated from each other and adjacent to the first and second sides S1 and S2, respectively.

The plurality of first barrier layers BRL1 may be extended in the first direction DR1 and may be adjacent to the first sides S1, respectively. The plurality of second barrier layers BRL2 may be extended in the second direction DR2 and may be adjacent to the second sides S2, respectively. A length of each of the plurality of second barrier layers BRL2 may be longer than a length of each of the plurality of first barrier layers BRL1.

The plurality of first barrier layers BRL1 may be arranged in the second direction DR2 and arranged between the light emitting elements OLED adjacent to each other in the second direction DR2. The plurality of second barrier layers BRL2 may be arranged in the first direction DR1 and arranged between the light emitting elements OLED adjacent to each other in the first direction DR1.

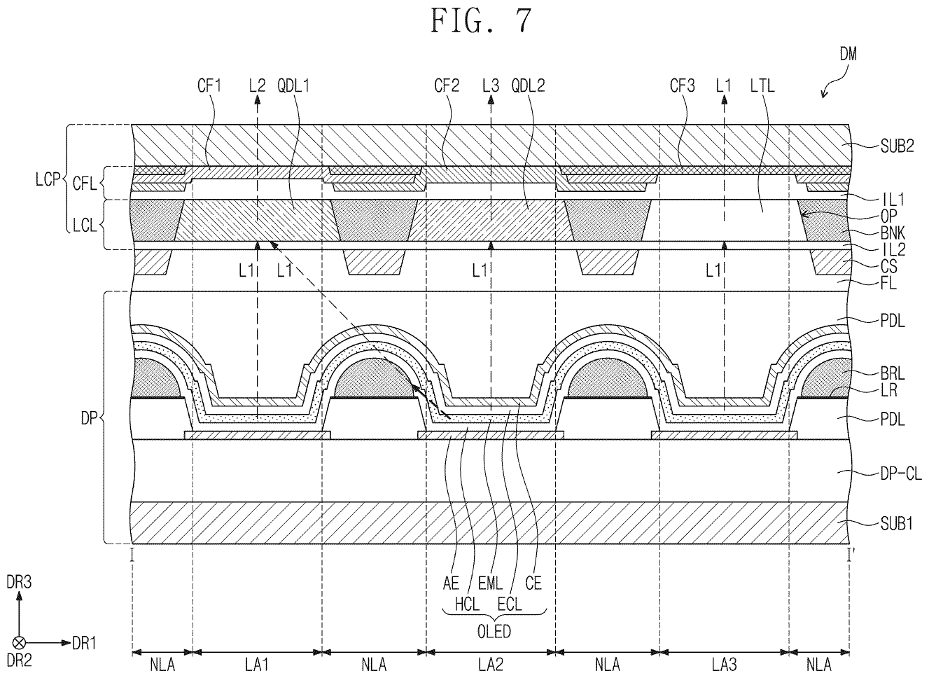

FIG. 7 is a cross-sectional view of a display module corresponding to line I-I′ illustrated in FIG. 6.

In FIG. 7, the circuit element layer DP-CL is shown as a single layer.

Referring to FIG. 7, the upper surface of the pixel defining film PDL may have liquid repellency. For example, the pixel defining film PDL may include a liquid-repellent layer LR that has liquid-repellent properties, and the liquid-repellent layer LR may define the upper surface of the pixel defining film PDL. The liquid-repellent layer LR may contain a fluorine compound to have liquid-repellent properties.

The plurality of barrier layers BRL may be arranged on the upper surface of the pixel defining film PDL. The plurality of barrier layers BRL may be in direct contact with the upper surface of the pixel defining film PDL. The plurality of barrier layers BRL may have black color.

The plurality of barrier layers BRL may have an upwardly convex curved surface. The plurality of barrier layers BRL may be formed to have an upwardly convex curved shape due to the upper surface of the pixel defining film PDL having liquid-repellent properties during a process. This process will be described in more detail later.

The light converting unit LCP may be arranged on the thin film encapsulation layer TFE. The light converting unit LCP may be attached to an upper surface of the thin film encapsulation layer TFE by the filler FL.

The light emitting areas LA may include a first light emitting area LA1, a second light emitting area LA2, and a third light emitting area LA3. The non-light emitting area NLA may be arranged between the first, second, and third light emitting areas LA1, LA2, and LA3. The light emitting elements OLED may generate a first light L1. In some embodiments, the first light L1 may be a blue light.

The color filter layer CFL may include a first color filter CF1, a second color filter CF2, a third color filter CF3, and a first insulating layer IL1. The light converting layer LCL may include a first quantum dot layer QDL1, a second quantum dot layer QDL2, a light-transmissive layer LTL, a bank layer BNK, and a second insulating layer IL2.

The first color filter CF1, the second color filter CF2, and the third color filter CF3 may be arranged under the second substrate SUB2. The first color filter CF1 may overlap the first light emitting area LA1, the second color filter CF2 may overlap the second light emitting area LA2, and the third color filter CF3 may overlap the third light emitting area LA3. The first color filter CF1 may include a red color filter. The second color filter CF2 may include a green color filter. The third color filter CF3 may include a blue color filter.

The first, second, and third color filters CF1, CF2, and CF3 may overlap the non-light emitting area NLA. For example, in the non-light emitting area NLA, the third color filter CF3, the first color filter CF1, and the second color filter CF2 may be sequentially stacked downward.

The third color filter CF3 that overlaps the non-light emitting area NLA between the second light emitting area LA2 and the third light emitting area LA3 may be extended from the third color filter CF3 that overlaps the third light emitting area LA3. The first color filter CF1 that overlaps the non-light emitting area NLA between the second light emitting area LA2 and the third light emitting area LA3 may be spaced and/or apart (e.g., spaced apart or separated) from and separately arranged in the first color filter CF1 that overlaps the first light emitting area LA1. The second color filter CF2 that overlaps the non-light emitting area NLA between the second light emitting area LA2 and the third light emitting area LA3 may be extended from the second color filter CF2 that overlaps the second light emitting area LA2.

The third color filter CF3 that overlaps the non-light emitting area NLA between the first light emitting area LA1 and the second light emitting area LA2 may be spaced and/or apart (e.g., spaced apart or separated) from and separately arranged in the third color filter CF3 that overlaps the third light emitting area LA3. The first color filter CF1 that overlaps the non-light emitting area NLA between the first light emitting area LA1 and the second light emitting area LA2 may be extended from the first color filter CF1 that overlaps the first light emitting area LA1. The second color filter CF2 that overlaps the non-light emitting area NLA between the first light emitting area LA1 and the second light emitting area LA2 may be extended from the second color filter CF2 that overlaps the second light emitting area LA2.

The first insulating layer IL1 may be arranged under the first, second, and third color filters CF1, CF2, and CF3. The first insulating layer IL1 may be an inorganic layer or an organic layer. The bank layer BNK, the first and second quantum dot layers QDL1 and QDL2, and the light-transmissive layer LTL may be arranged under the first insulating layer IL1.

Openings OP in which the first and second quantum dot layers QDL1 and QDL2 and the light-transmissive layer LTL are to be arranged may be defined in the bank layer BNK. The openings OP may overlap the first, second, and third light emitting areas LA1, LA2, and LA3. The bank layer BNK may overlap the non-light emitting area NLA. The bank layer BNK may have black color. The first and second quantum dot layers QDL1 and QDL2 and the light-transmissive layer LTL may be arranged in the openings OP.

The first and second quantum dot layers QDL1 and QDL2 and the light-transmissive layer LTL may overlap the first, second, and third light emitting areas LA1, LA2, and LA3, respectively. The first quantum dot layer QDL1 may overlap the first light emitting area LA1, the second quantum dot layer QDL2 may overlap the second light emitting area LA2, and the light-transmissive layer LTL may overlap the third light emitting area LA3. Thus, the first and second quantum dot layers QDL1 and QDL2 and the light-transmissive layer LTL may be arranged on the light emitting elements OLED and may overlap the light emitting elements OLED, respectively.

The second insulating layer IL2 may be arranged under the bank layer BNK, the first and second quantum dot layers QDL1 and QDL2, and the light-transmissive layer LTL. The filler FL may be arranged between the second insulating layer IL2 and the thin film encapsulation layer TFE.

The display module DM may further include a plurality of column spacers CS. The column spacers CS may be arranged under the second insulating layer IL2. The filler FL may be arranged under the second insulating layer IL2 to cover the column spacers CS.

The first light L1 generated by the light emitting elements OLED may be provided to the first and second quantum dot layers QDL1 and QDL2 and the light-transmissive layer LTL. The first light L1 generated by the light emitting element OLED overlapping the first light emitting area LA1 may be provided to the first quantum dot layer QDL1, and the first light L1 generated by the light emitting element OLED overlapping the second light emitting area LA2 may be provided to the second quantum dot layer QDL2. The first light L1 generated by the light emitting element OLED overlapping the third light emitting area LA3 may be provided to the light-transmissive layer LTL.

The first quantum dot layer QDL1 may convert the first light L1 into a second light L2. The second quantum dot layer QDL2 may convert the first light L1 into a third light L3. In some embodiments, the second light L2 may be a red light, and the third light L3 may be a green light. The first quantum dot layer QDL1 may include first quantum dots, and the second quantum dot layer QDL2 may include second quantum dots. The light-transmissive layer LTL may include light scattering particles for scattering a light.

The first quantum dots may convert the first light L1 having a blue wavelength band into the second light L2 having a red wavelength band. The second quantum dots may convert the first light L1 having a blue wavelength band into the third light L3 having a green wavelength band. The first and second quantum dots may scatter the second and third lights L2 and L3. The light-transmissive layer LTL may be to transmit the first light L1 without performing a light converting operation. The light transmissive layer LTL may output a light by scattering the first light L1 through the light scattering particles.

The first quantum dot layer QDL1 may output the second light L2, the second quantum dot layer QDL2 may output the third light L3, and the light-transmissive layer LTL may output the first light L1. Thus, a set or predetermined image may be displayed by the second light L2, third light L3, and first light L1 that display red, green, and blue colors.

A portion of the first light L1 may not be converted by the first quantum dots, may pass through the first quantum dot layer QDL1, and may be provided to the first color filter CF1. For example, the first light L1 that is not in contact with the first quantum dots and thus is not converted into the second light L2 may be present. The first color filter CF1 may shield lights having other colors. The first light L1 that is not converted by the first quantum dot layer QDL1 may be shielded by the first color filter CF1 having the red color filter and may not be output to the upper side.

A portion of the first light L1 may not be converted by the second quantum dots, may pass through the second quantum dot layer QDL2, and may be provided to the second color filter CF2. For example, the first light L1 that is not in contact with the second quantum dots and thus is not converted into the third light L3 may be present. The second color filter CF2 may shield lights having other colors. The first light L1 that is not converted by the second quantum dot layer QDL2 may be shielded by the second color filter CF2 having the green color filter and may not be output to the upper side.

An external light may be provided toward the display device DD. When the external light is reflected by the display panel DP and provided back to the external user, the user may visually recognize the external light, like a mirror.

The first, second, and third color filters CF1, CF2, and CF3 may prevent or reduce reflection of the external light. For example, the first, second, and third color filters CF1, CF2, and CF3 may filter the external light into a red light, a green light, and a blue light. For example, the first, second, and third color filters CF1, CF2, and CF3 may filter the external light into lights having the same colors as the second light L2, the third light L3, and the first light L1. In this case, the external light may not be visually recognized by the user.

The black bank layer BNK may shield the light that is not necessary in the non-light emitting area NLA. For example, the bank layer BNK may prevent or reduce color mixing between the first light L1, the second light L2, and the third light L3 in the non-light emitting area NLA.

The column spacers CS may maintain a gap between the first substrate SUB1 and the second substrate SUB2. A gap between an upper surface and a lower surface of the display module DM may be maintained by the column spacers CS.

Each of the plurality of barrier layers BRL may shield the first light L1 traveling from each of the light emitting elements OLED in a lateral direction (e.g., the barrier layer BRL may prevent the first light L1 traveling from a direction that is away from the travelling direction of the first light L1 which travels from the light emitting element OLED where there is no barrier layer BRL). If (e.g., when) the plurality of barrier layers BRL is not arranged on the pixel defining film PDL, the following occasions may occur.

The first light L1 generated by the light emitting element OLED overlapping the second light emitting area LA2 may travel in the third direction DR3, but a portion of the first light L1 may travel in the lateral direction (e.g., a direction that is away from the travelling direction of the first light L1 which travels from the light emitting element OLED where there is no barrier layer BRL), as indicated by diagonal thin dotted arrows. The portion of the first light L1 traveling in the lateral direction may be provided to the first quantum dot layer QDL1 being adjacent to the second light emitting area LA2 and overlapping the first light emitting area LA1.

The first light L1 generated by the light emitting element OLED overlapping the second light emitting area LA2 should be provided to the second quantum dot layer QDL2, but the portion of the first light L1 is provided to the first quantum dot layer QDL1, and thus an undesired light converting operation may be performed. In this case, a color matching rate may be degraded. The color matching rate may be defined as an indicator indicating how much a color displayed by the display device DD is matched with an actual color.

In one or more embodiments of the present disclosure, the plurality of barrier layers BRL may shield the first light L1 traveling in the lateral direction from the light emitting elements OLED (e.g., a direction that is away from the travelling direction of the first light L1 which travels from the light emitting element OLED where there is no barrier layer BRL), as indicated by diagonal thick dotted arrows. Thus, performance of an undesired light converting operation may be prevented or reduced, and thus the color matching rate may be improved.

In other words, each barrier layer BRL prevents or reduces the first light L1 from traveling laterally from the light emitting elements OLED. Without these barrier layers, the first light L1 from the OLEDs in the second light emitting area LA2 can travel laterally and reach adjacent quantum dot layers, causing undesired light conversion and reducing the color matching rate. The color matching rate indicates how accurately the display device DD matches the actual color. By shielding the lateral travel of light, the barrier layers BRL improve the color matching rate by preventing or reducing unwanted light conversion.

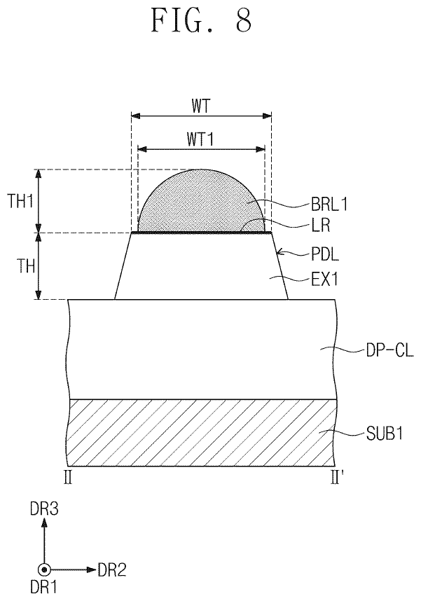

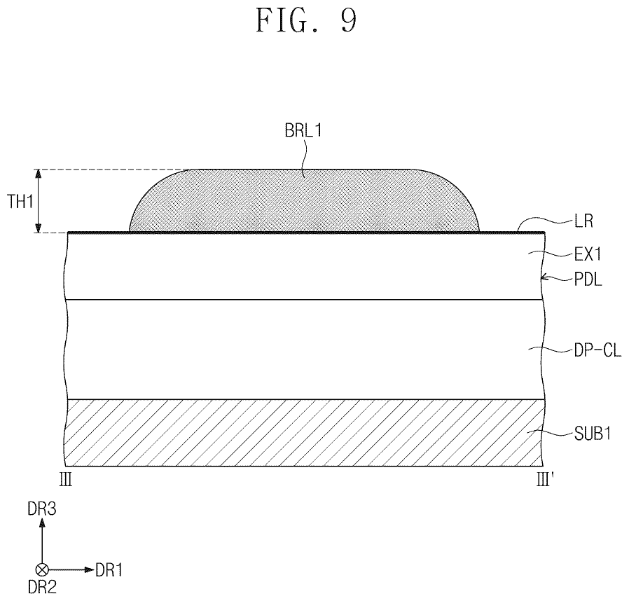

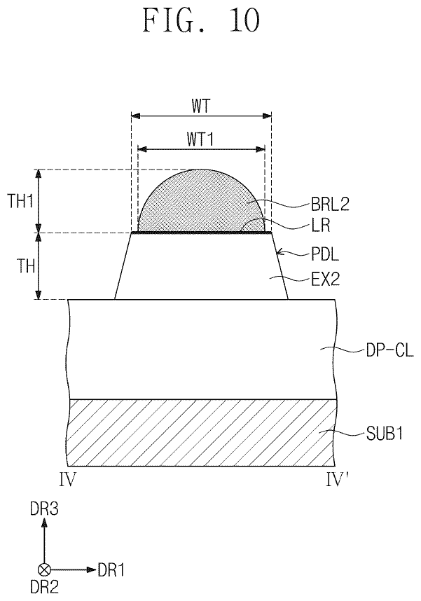

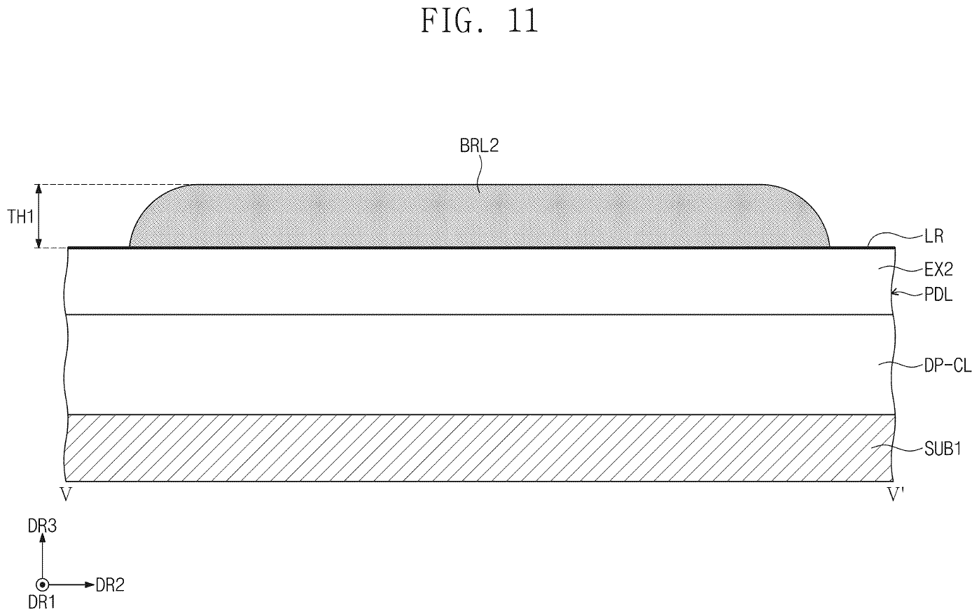

FIG. 8 is a cross-sectional view along line II-II′ illustrated in FIG. 6. FIG. 9 is a cross-sectional view along line III-III′ illustrated in FIG. 6. FIG. 10 is a cross-sectional view of line IV-IV′ illustrated in FIG. 6. FIG. 11 is a cross-sectional view along line V-V′ illustrated in FIG. 6.

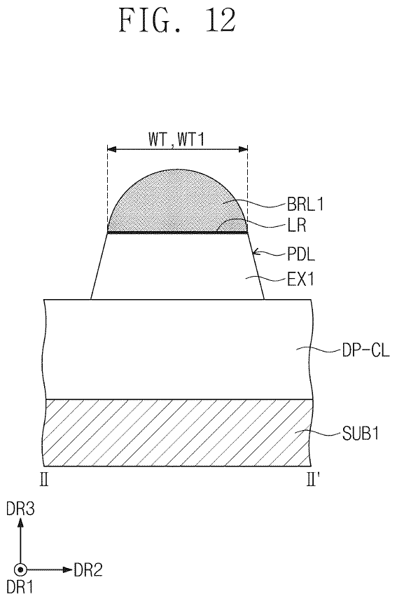

FIGS. 8 to 11 illustrate the display module DM without showing a portion of the first substrate SUB1, a portion of the circuit element layer DP-CL, a portion of the pixel defining film PDL, and the first and second barrier layers BRL1 and BRL2, and the other components. Hereinafter, FIGS. 12 to 17 that are similar cross sectional views will be illustrated similarly to FIGS. 8 to 11.

Referring to FIGS. 8 and 9, the first barrier layer BRL1 may be arranged on the upper surface of the pixel defining film PDL. The first barrier layer BRL1 may be arranged on the liquid-repellent layer LR having liquid-repellent properties. A cross section of the first barrier layer BRL1 cut in the second direction DR2 that crosses (intersects) the first direction DR1 which is a direction in which the first barrier layer BRL1 extends may have an upwardly convex curved shape.

Referring to FIG. 9, the first barrier layer BRL1 may be arranged on the first extension portion EX1 and extended in the first direction DR1. Both sides of the first barrier layer BRL1, which are opposite to each other in the first direction DR1, may have a curved shape. An upper surface of the first barrier layer BRL1 may have a flat surface.

Hereinafter, in the specification, a thickness may be defined as a value measured in the third direction DR3, and a width may be defined as a value measured in the first direction DR1 or the second direction DR2.

Referring to FIG. 8, a lower surface of the first barrier layer BRL1 may be in direct contact with the upper surface of the pixel defining film PDL. In the second direction DR2, the lower surface of the first barrier layer BRL1 may have a first width WT1. The first width WT1 may be smaller than a width WT of the upper surface of the pixel defining film PDL in the second direction DR2.

In the third direction DR3, the first barrier layer BRL1 may have a first thickness TH1. The first thickness TH1 may be smaller than a thickness TH of the pixel defining film PDL in the third direction DR3. In some embodiments, the first thickness TH1 may be greater than 0.3 times and smaller than 1 times the thickness TH.

In other words, referring to FIGS. 8 and 9, the first barrier layer BRL1 is arranged on the upper surface of the pixel defining film PDL and on the liquid-repellent layer LR. A cross-section of the first barrier layer BRL1, cut in the second direction DR2 crossing (intersecting) the first direction DR1, has an upwardly convex curved shape. As shown in FIG. 9, the first barrier layer BRL1 is positioned on the first extension portion EX1 and extends in the first direction DR1, with both sides having a curved shape and the upper surface being flat. In this specification, thickness is measured in the third direction DR3, and width is measured in the first (DR1) or second direction (DR2). Referring to FIG. 8, the lower surface of the first barrier layer BRL1 is in direct contact with the upper surface of the pixel defining film PDL. The first width WT1 of the lower surface in the second direction DR2 is smaller than the width WT of the upper surface of the PDL. In the third direction DR3, the first barrier layer BRL1 has a first thickness TH1 that is smaller than the thickness TH of the pixel defining film PDL, typically between 0.3 and 1 times the thickness TH.

Referring to FIGS. 10 and 11, the second barrier layer BRL2 may be arranged on the upper surface of the pixel defining film PDL. The second barrier layer BRL2 may be arranged on the liquid-repellent layer LR having liquid-repellent properties. A cross section of the second barrier layer BRL2 cut in the first direction DR1 that crosses (intersects) the second direction DR2 which is a direction in which the second barrier layer BRL2 extends may have an upwardly convex curved shape.

Referring to FIG. 11, the second barrier layer BRL2 may be arranged on the second extension portion EX2 and extended in the second direction DR2. Both sides of the second barrier layer BRL2, which are opposite to each other in the second direction DR2, may have a curved shape. An upper surface of the second barrier layer BRL2 may have a flat surface.

Referring to FIG. 10, a lower surface of the second barrier layer BRL2 may be in direct contact with the upper surface of the pixel defining film PDL. In the second direction DR2, the lower surface of the second barrier layer BRL2 may have the first width WT1 that is smaller than the width WT of the pixel defining film PDL. In the third direction DR3, the second barrier layer BRL2 may have the first thickness TH1 that is smaller than the thickness TH of the pixel defining film PDL.

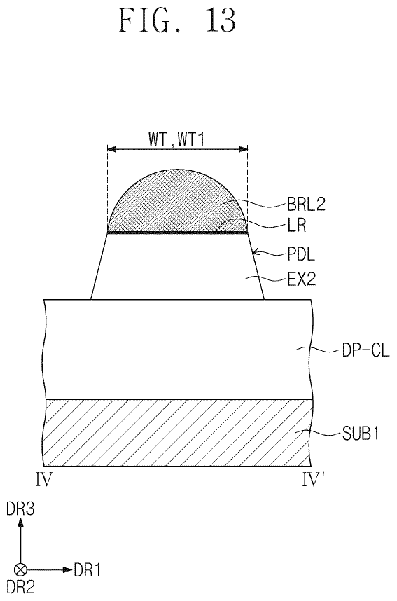

FIG. 12 is a view illustrating another configuration of the first barrier layer corresponding to the cross-sectional view along line II-II′ illustrated in FIG. 6. FIG. 13 is a view illustrating another configuration of a second barrier layer corresponding to the cross-sectional view along line IV-IV′ illustrated in FIG. 6.

Hereinafter, configurations illustrated in FIGS. 12 and 13 will be described while focused on configurations different from those illustrated in FIGS. 8 and 9.

Referring to FIGS. 8, 9, 12, and 13, the first width WT1 of the lower surface of each of the first and second barrier layers BRL1 and BRL2 in contact with the upper surface of the pixel defining film PDL may be smaller than the width WT of the upper surface of the pixel defining film PDL, but one or more embodiments of the present disclosure is not limited thereto. For example, as illustrated in FIGS. 11 and 12, the first width WT1 of the lower surface of each of the first and second barrier layers BRL1 and BRL2 may be the same as the width WT of the pixel defining film PDL. In some embodiments, the first width WT1 may be set to 0.9 times to 1 times the width WT.

In other words, referring to FIGS. 10 and 11, the second barrier layer BRL2 is arranged on the upper surface of the pixel defining film PDL and the liquid-repellent layer LR. A cross-section of second barrier layer BRL2, cut in the first direction DR1 intersecting the second direction second barrier layer DR2, has an upwardly convex curved shape. As shown in FIG. 11, second barrier layer BRL2 extends in the second direction DR2 with both sides curved and the upper surface flat. FIG. 10 shows that the lower surface of second barrier layer BRL2 is in direct contact with the PDL, with a width WT1 smaller than the pixel defining film PDL's width WT in the second direction DR2 and a thickness TH1 smaller than the pixel defining film's PDL's thickness TH in the third direction DR3. FIGS. 12 and 13 illustrate alternative configurations of the barrier layers, focusing on differences from FIGS. 8 and 9. The lower surface width WT1 of each of the first barrier layer BRL1 and the second barrier layer BRL2 may be the same as or smaller than the pixel defining film's PDL's width WT, typically set between 0.9 to 1 times the pixel defining film's PDL's width.

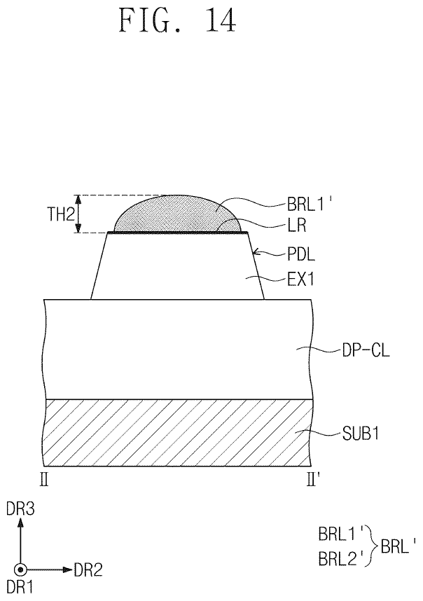

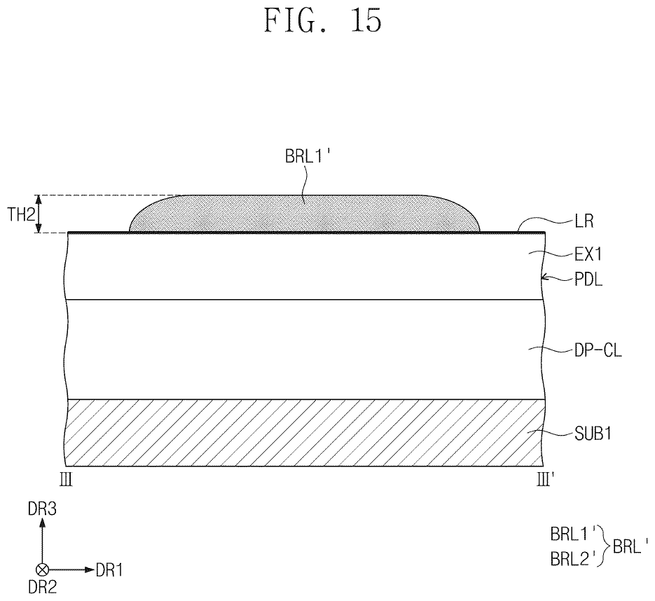

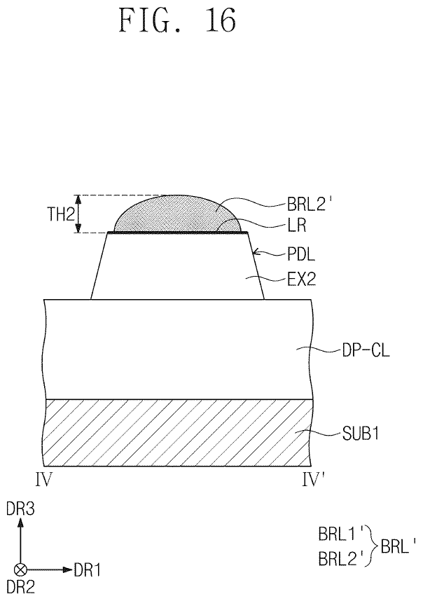

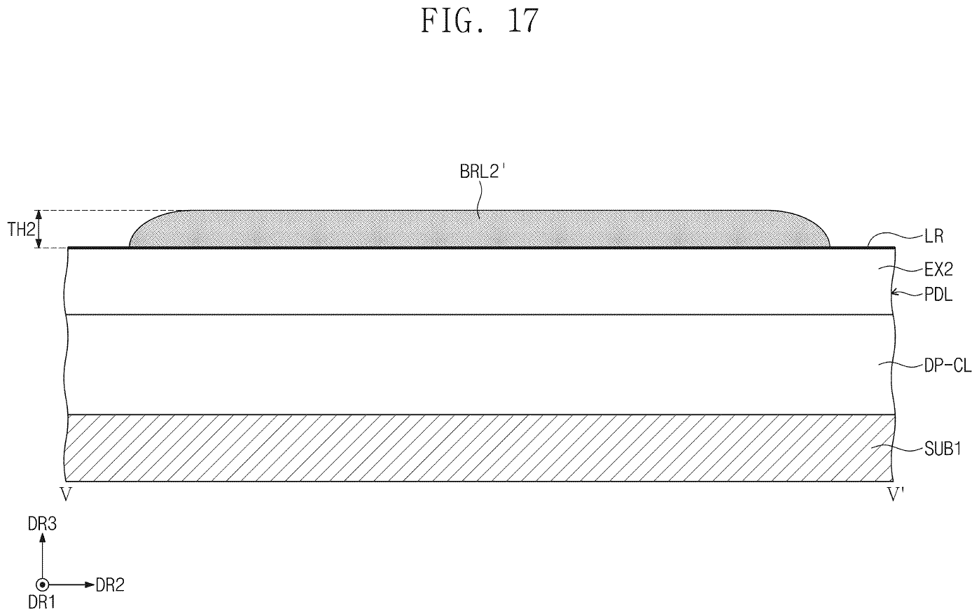

FIG. 14 is a view illustrating another configuration of the first barrier layer corresponding to the cross-sectional view along line II-II′ illustrated in FIG. 6. FIG. 15 is a view illustrating another configuration of the first barrier layer corresponding to the cross-sectional view along line III-III′ illustrated in FIG. 6. FIG. 16 is a view illustrating another configuration of the second barrier layer corresponding to the cross-sectional view along line IV-IV′ illustrated in FIG. 6. FIG. 17 is a view illustrating another configuration of the second barrier layer corresponding to the cross-sectional view along line V-V′ illustrated in FIG. 6.

Hereinafter, configurations of first and second barrier layers BRL1′ and BRL2′ illustrated in FIGS. 14 to 17 will be described while focused on configurations different from those of the first and second barrier layers BRL1 and BRL2 illustrated in FIGS. 8 to 11.

Referring to FIGS. 14 to 17, the first and second barrier layers BRL1′ and BRL2′ of a barrier layer BRL′ may have a second thickness TH2 in the third direction DR3. The second thickness TH2 may be smaller than the first thickness TH1. For example, the first and second barrier layers BRL1′ and BRL2′ may have a thickness smaller than the thickness of the first and second barrier layers BRL1 and BRL2 illustrated in FIGS. 8 to 11.

The first and second barrier layers BRL1 and BRL2 and the first and second barrier layers BRL1′ and BRL2′ may be formed by providing ink to the upper surface of the pixel defining film PDL. A thickness of the ink provided on the pixel defining film PDL and a spread length of the ink may be changed depending on surface energy of the upper surface of the pixel defining film PDL.

In one or more embodiments of the present disclosure, by differently setting the surface energy of the upper surface of the pixel defining film PDL, the thickness of the ink provided on the pixel defining film PDL and the spread length of the ink may be adjusted. Thus, the barrier layers BRL and BRL′ having one or more suitable thicknesses may be formed. This process will be described in more detail later.

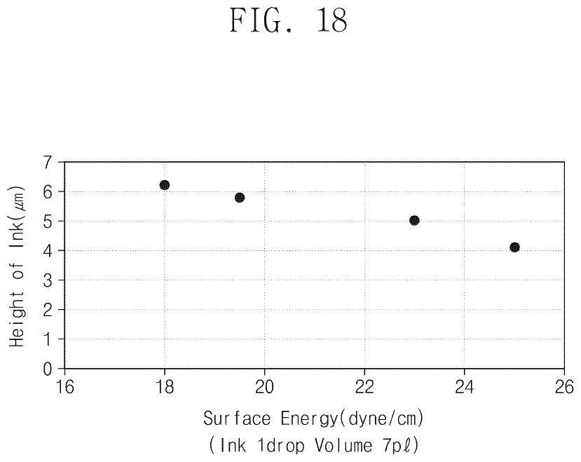

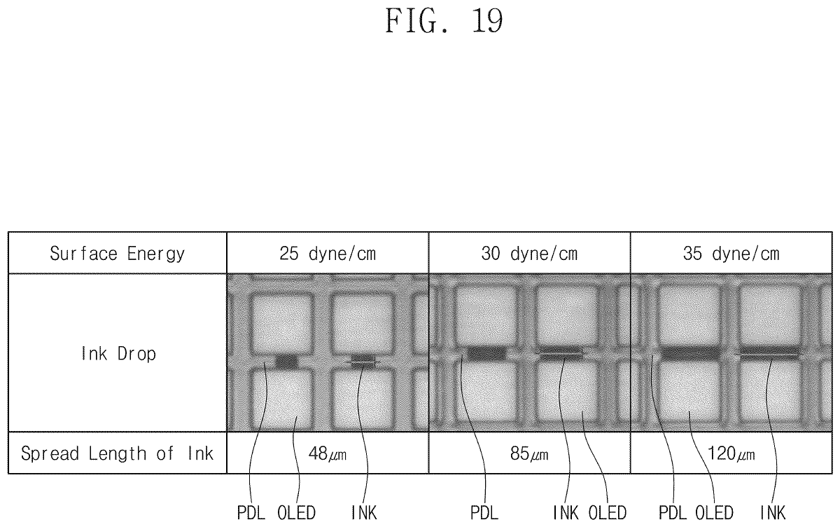

FIG. 18 is a graph depicting a height of ink provided on an upper surface of a pixel defining film according to surface energy of the upper surface of the pixel defining film. FIG. 19 is a table illustrating a spread length of the ink provided on the upper surface of the pixel defining film according to the surface energy of the upper surface of the pixel defining film.

In FIG. 18, a horizontal axis may represent the surface energy of the upper surface of the pixel defining film PDL, and a vertical axis may represent a height of the ink provided on the pixel defining film PDL. In FIG. 18, the height of the ink is indicated by dots.

In FIG. 19, a test is performed in a state in which the light emitting areas OLED are formed in a square shape and an ink INK is provided on the pixel defining film PDL between the light emitting areas OLED. FIG. 19 illustrates a state of the ink INK horizontally spread between the light emitting areas OLED.

Referring to FIGS. 18 and 19, as the surface energy may become greater, the height of the ink INK may become smaller. As the surface energy becomes greater or increases, the spread length of the ink INK may become longer (further spread). In FIGS. 18 and 19, units of the thickness and the length are micrometers. Furthermore, the amount of ink discharged from a nozzle at one time is 7 picoliters (pl).

The display devices DD having one or more suitable resolutions may be manufactured. For example, the display device DD having a first resolution and the display device DD having a second resolution greater than the first resolution may be manufactured. In this case, a size of each pixel having the first resolution may be larger than a size of each pixel having the second resolution. As the size of the pixels (e.g., the plurality of pixels PX) becomes larger (increases), a barrier layer having a large thickness may be desired or required, and as the size of the pixels (e.g., the plurality of pixels PX) becomes smaller (decreases), a barrier layer having a small thickness may be desired or required.

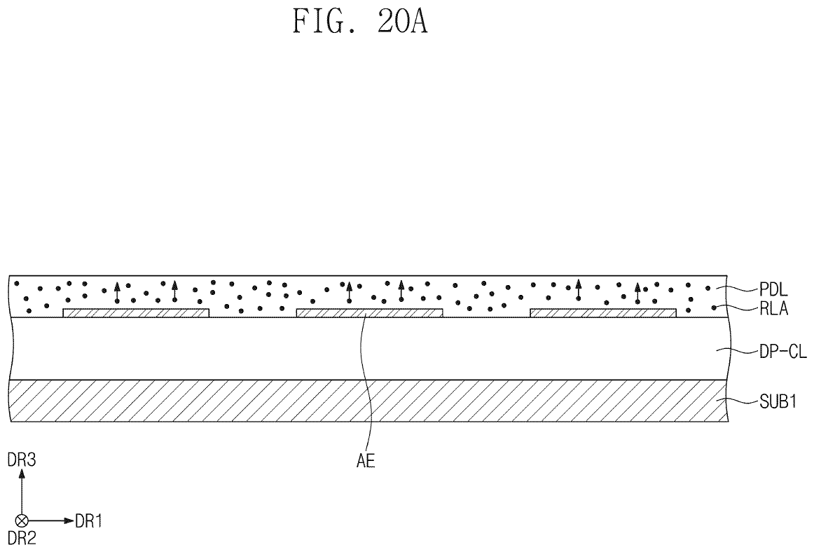

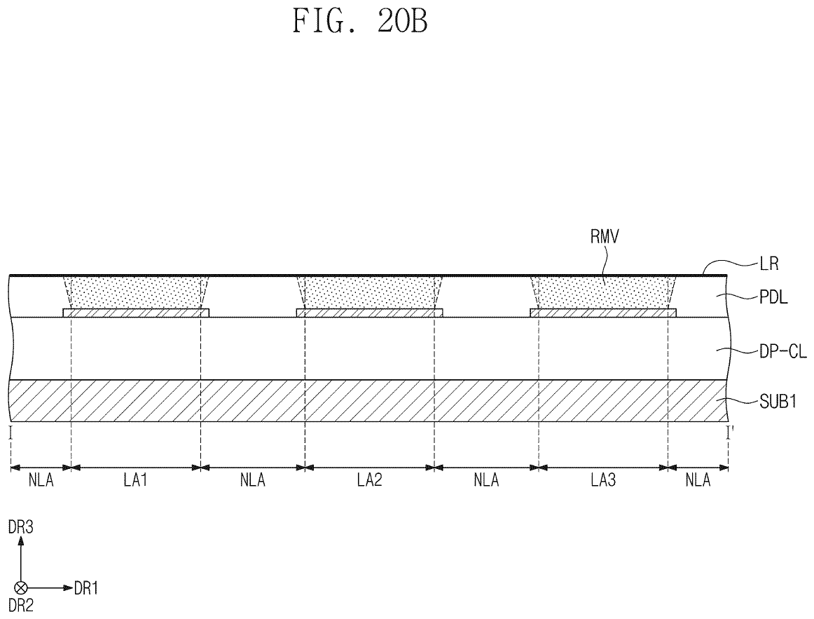

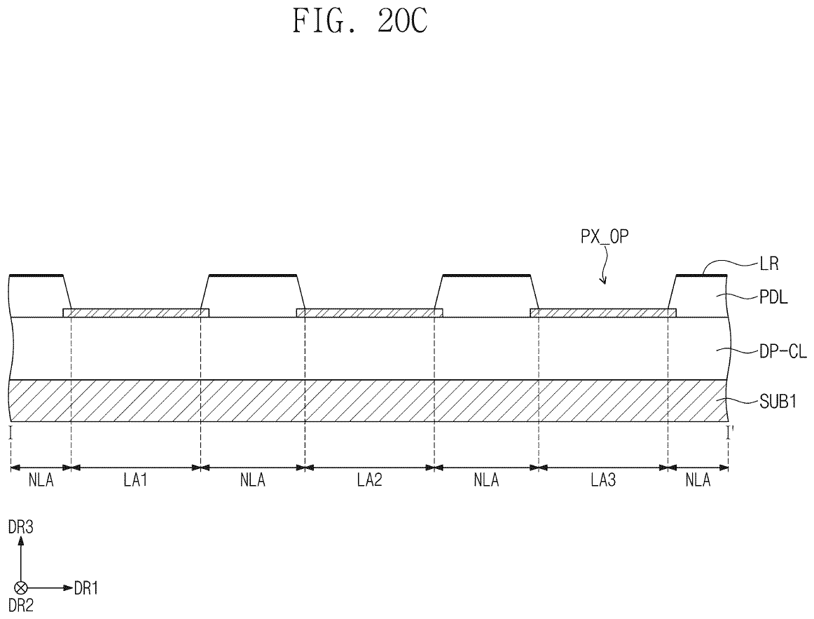

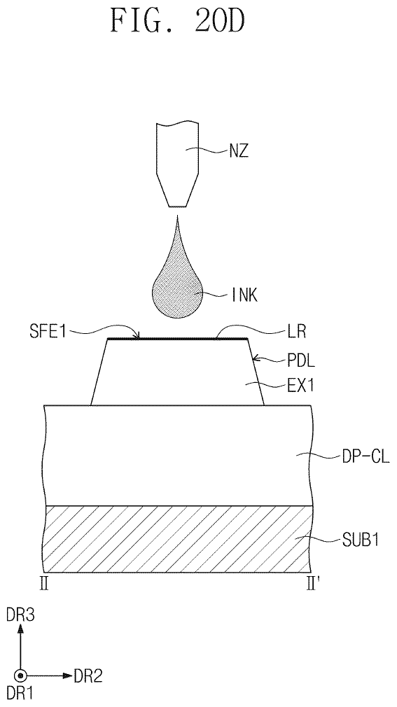

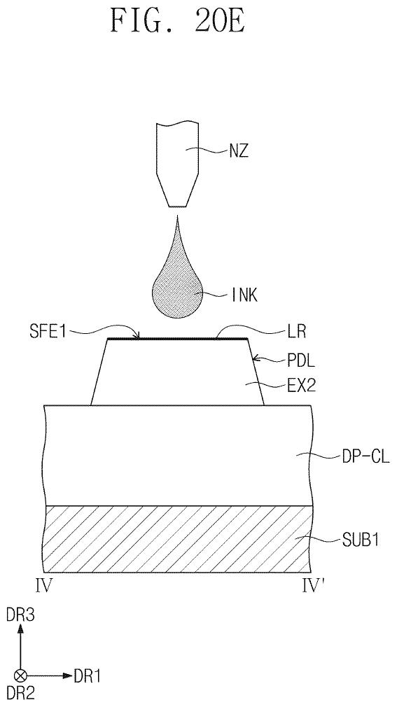

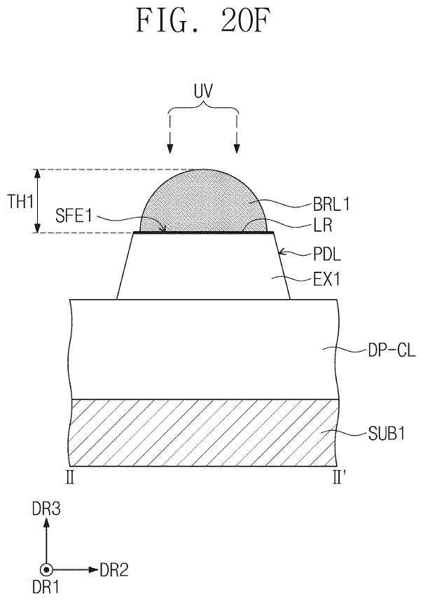

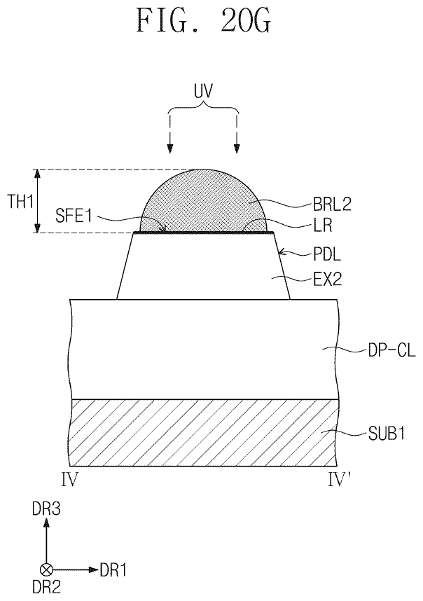

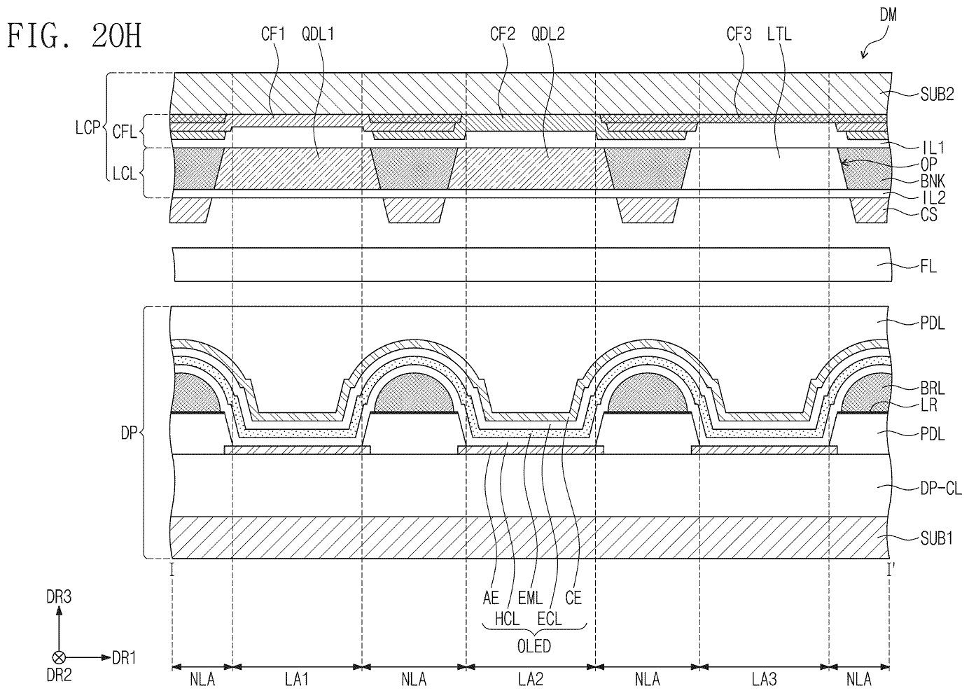

The surface energy of the upper surface of the pixel defining film PDL may be adjusted by the amount of a liquid-repellent additive (illustrated in FIG. 20A). The pixel defining film PDL may have first surface energy corresponding to the first resolution or second surface energy corresponding to the second resolution. The second surface energy may be greater than the first surface energy.

Hereinafter, referring to FIGS. 20A to 20H, FIG. 21, and FIGS. 22A to 22D, a method of forming the barrier layer BRL if (e.g., when) the pixel defining film PDL has the first surface energy will be described.

FIGS. 20A to 20H are views for describing a method of manufacturing a display device, according to one or more embodiments of the present disclosure.

FIGS. 20A and 20B among FIGS. 20A to 20H are views illustrating a method of forming a liquid-repellent layer. FIGS. 20D to 20G among FIGS. 20A to 20H are views illustrating a method of forming the first and second barrier layers BRL1 and BRL2 illustrated in the cross sections in the FIGS. 8 and 10. FIGS. 20A to 20C and 20H illustrate a cross section corresponding to FIG. 7, and FIGS. 20D to 20G illustrate a cross section corresponding to FIGS. 8 and 10.

Referring to FIGS. 20A and 20B, the pixel defining film PDL may be provided on the first substrate SUB1. The pixel defining film PDL may include an organic layer. A liquid-repellent additive RLA containing a fluorine compound may be arranged in the pixel defining film PDL. The liquid-repellent additive RLA may have a property of coming into contact with air.

If (e.g., when) the pixel defining film PDL is provided on the circuit element layer DP-CL, the liquid-repellent additive RLA, which has a property of coming into contact with air, may move upward. The liquid-repellent additive RLA may move to the upper side of the circuit element layer DP-CL to form the liquid-repellent layer LR. The liquid-repellent layer LR may define the upper surface of the pixel defining film PDL. Thus, the upper surface of the pixel defining film PDL may be formed as the liquid-repellent layer LR.

Referring to FIGS. 20B and 20C, removal portions RMV of the pixel defining film PDL overlapping the openings PX_OP are removed, and thus the openings PX_OP overlapping the light emitting areas LA1, LA2, and LA3 may be defined in the pixel defining film PDL. The removal portions RMV may be removed by a photo process, where a description of the photo process will not be provided.

Referring to FIGS. 20D and 20E, the upper surface of the pixel defining film PDL may have first surface energy SFE1. An inkjet printing process may be utilized to provide the ink INK to the upper surface of the pixel defining film PDL through a nozzle NZ. The ink INK may be provided on an upper surface of the first extension portion EX1 and an upper surface of the second extension portion EX2. The ink INK may be provided on the liquid-repellent layer LR.

Referring to FIGS. 20F and 20G, if (e.g., when) a solution is provided on an upper surface of a liquid-repellent solid, the solution has a property of clumping together, and as a result, the solution may have a convex shape (e.g., a shape that curves outward). Thus, if (e.g., when) the ink INK is provided to the liquid-repellent layer LR, the ink INK has a property of clumping together and thus may have an upwardly convex curved shape.

If (e.g., when) the upper surface of the pixel defining film PDL has the first surface energy SFE1, the ink INK provided on the upper surface of the pixel defining film PDL may have the first thickness TH1 in the third direction DR3. The ink INK, which has a property of clumping together, may be formed to have the first thickness TH1. As the ink INK is cured, the first barrier layer BRL1 may be formed on the first extension portion EX1, and the second barrier layer BRL2 may be formed on the second extension portion EX2.

Referring to FIG. 20H, the light emitting elements OLED may be provided in the openings PX_OP, the thin film encapsulation layer TFE may be provided on the light emitting elements OLED, and thus the display panel DP may be manufactured. Thereafter, the light converting unit LCP including the color filters CF1, CF2, and CF3, the quantum dot layers QDL1 and QDL2, and/or the light-transmissive layer LTL may be provided on the light emitting elements OLED, so that the display module DM may be manufactured. The light converting unit LCP may be connected to (e.g., bonded to) the display panel DP through the filler FL having an adhesive function.

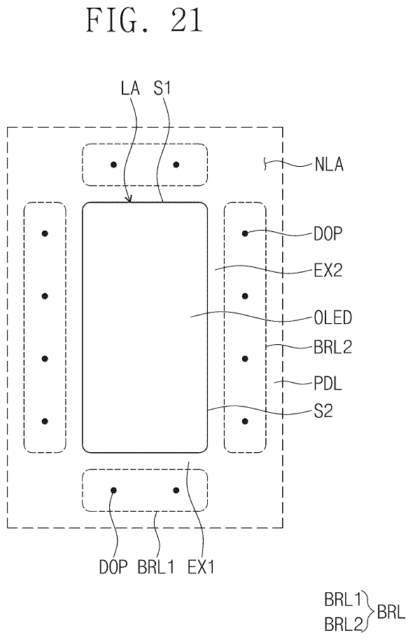

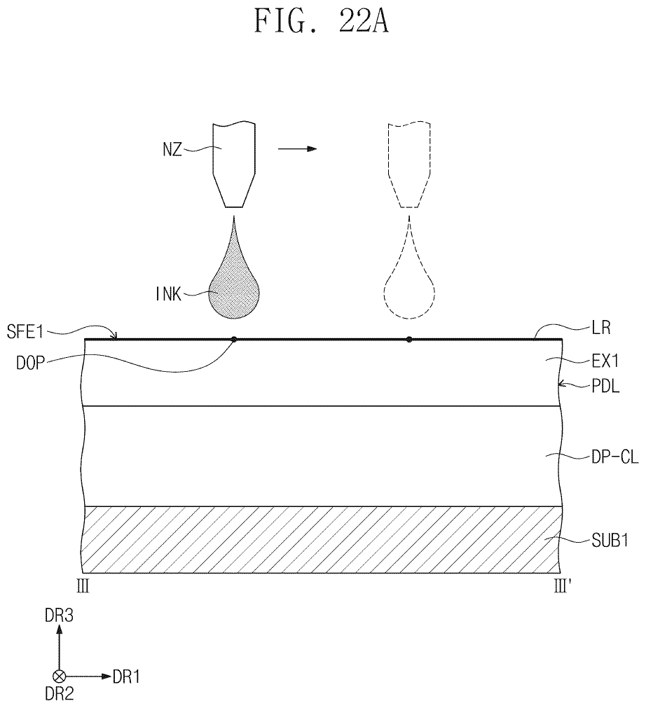

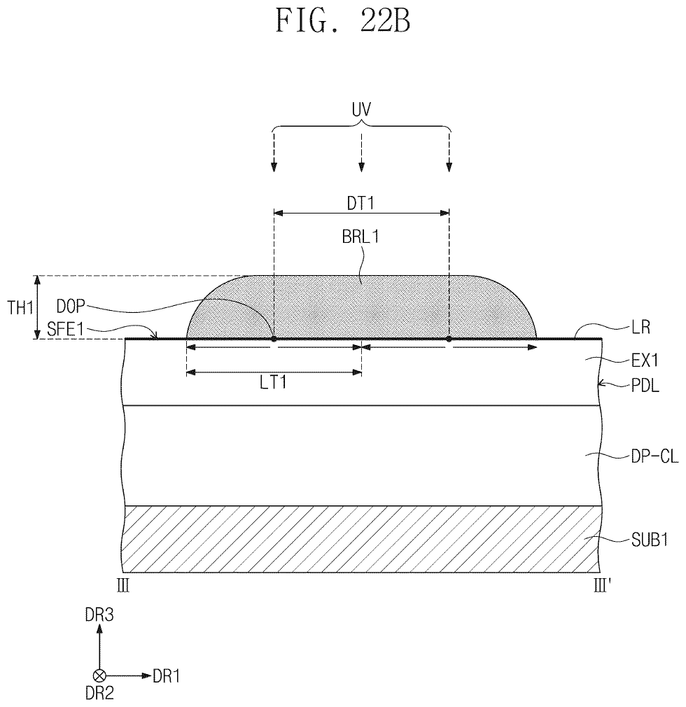

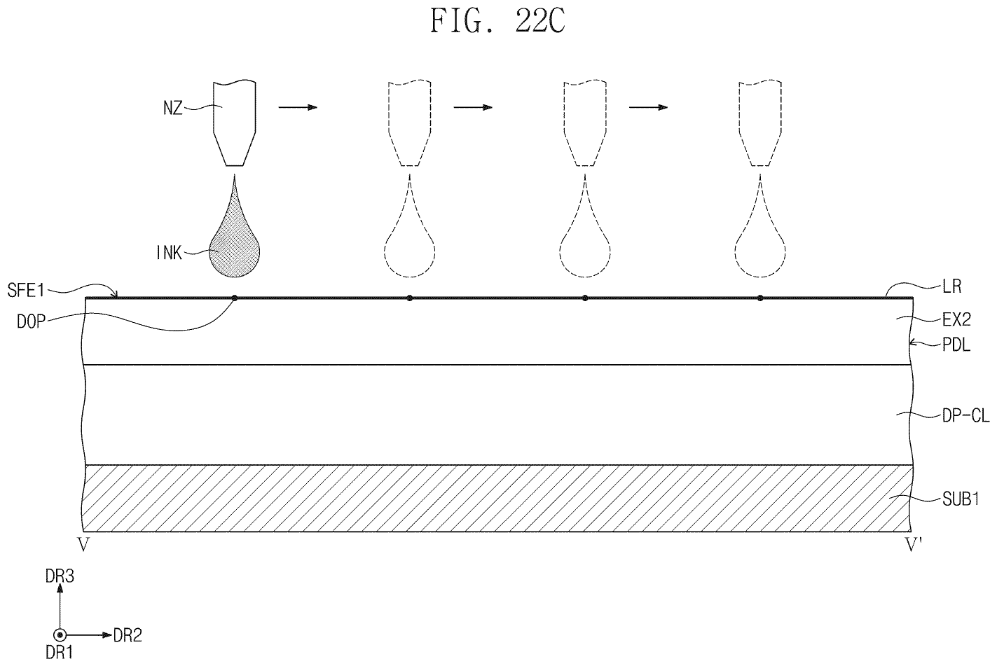

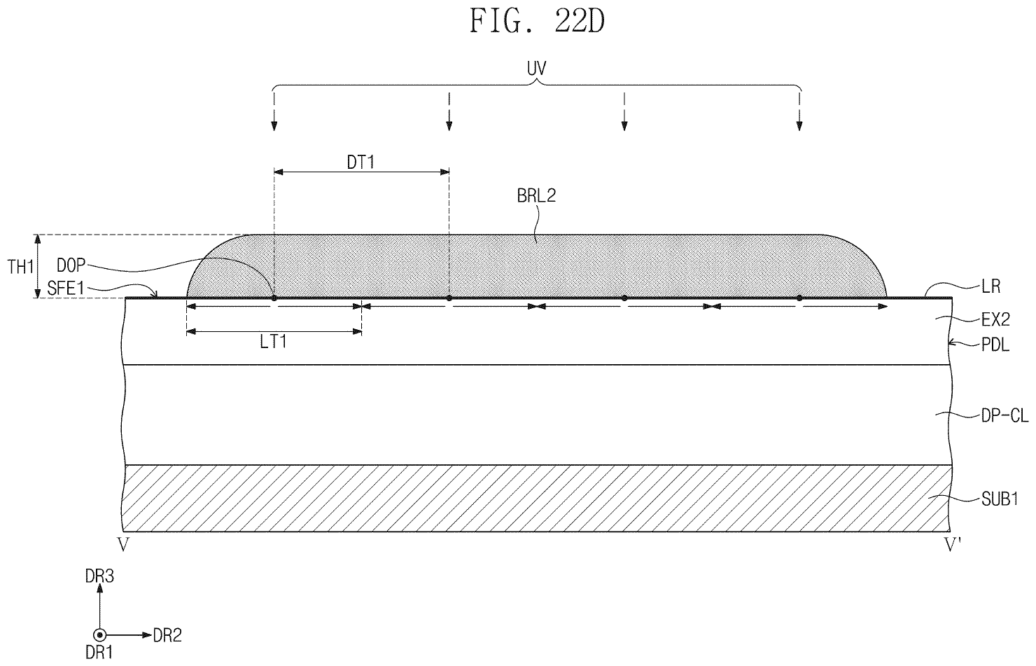

FIG. 21 is a view illustrating the plurality of drop points of ink in the method of manufacturing a display device if (e.g., when) the upper surface of the pixel defining film has first surface energy. FIGS. 22A to 22D are views for describing a method of forming the first and second barrier layers illustrated in the cross sections of FIGS. 9 and 11 if (e.g., when) the upper surface of the pixel defining film has the first surface energy.

FIG. 21 is a plan view illustrating the plurality of drop points DOP defined around the one light emitting element OLED.

Referring to FIG. 21, the plurality of drop points DOP may be defined on the upper surface of the pixel defining film PDL. The plurality of drop points DOP may be arranged along the first and second sides S1 and S2 of the light emitting area LA. The ink INK may be provided at the plurality of drop points DOP.

At least one drop point DOP may be defined on an upper surface of each of the first and second extension portions EX1 and EX2. In FIG. 21, two drop points DOP are defined on an upper surface of each of the first extension portions EX1, and four drop points DOP are defined on an upper surface of each of the second extension portions EX2. However, the number of drop points DOP is not limited thereto. More drop points DOP may be defined on the second extension portions EX2 than on the first extension portions EX1.

The ink INK may be provided to the plurality of drop points DOP to form the first and second barrier layers BRL1 and BRL2. In FIG. 21, the first and second barrier layers BRL1 and BRL2 are illustrated as dotted lines.

Referring to FIGS. 21, 22A, and 22B, the ink INK may be provided to each of the plurality of drop points DOP defined on the upper surface of the first extension portion EX1. While moving in the first direction DR1, the nozzle NZ may not continuously discharge the ink INK and may discharge a set or predetermined amount of ink only at each of the plurality of drop points DOP.

At each of the plurality of drop points DOP, the ink INK may be spread in both directions (e.g., the first direction DR1 and a direction opposite to the first direction DR1 simultaneously) along the first side S1. The ink INK spread in the plurality of drop points DOP may be combined with each other. The ink INK may be cured to form the first barrier layer BRL1 on the first extension portion EX1.

A spread length of the ink INK at each of the plurality of drop points DOP on the first extension portion EX1 may be defined as a first length LT1. A distance between the plurality of drop points DOP adjacent to each other on the first extension portion EX1 may be defined as a first distance DT1.

Referring to FIGS. 21, 22C, and 22D, the ink INK may be provided to each of the plurality of drop points DOP defined on the upper surface of the second extension portion EX2. Because the second extension portion EX2 is formed longer than the first extension portion EX1, more drop points DOP may be defined on the second extension portion EX2.

The ink INK may be spread in both directions (e.g., the second direction DR2 and a direction opposite to the second direction DR2 simultaneously) along the second side S2. The ink INK may be cured to form the second barrier layer BRL2 on the second extension portion EX2.

A spread length of the ink INK at each of the plurality of drop points DOP on the second extension portion EX2 may be defined as the first length LT1. A distance between the plurality of drop points DOP adjacent to each other on the second extension portion EX2 may be defined as the first distance DT1.

According to the above-described manufacturing method, if (e.g., when) the upper surface of the pixel defining film PDL has the first surface energy SFE1, the ink INK provided to each of the plurality of drop points DOP may be spread to have the first thickness TH1 and have the first length LT1 in the first direction DR1. Furthermore, if (e.g., when) the upper surface of the pixel defining film PDL has the first surface energy SFE1, a distance between the plurality of drop points DOP adjacent to each other may be set to the first distance DT1.

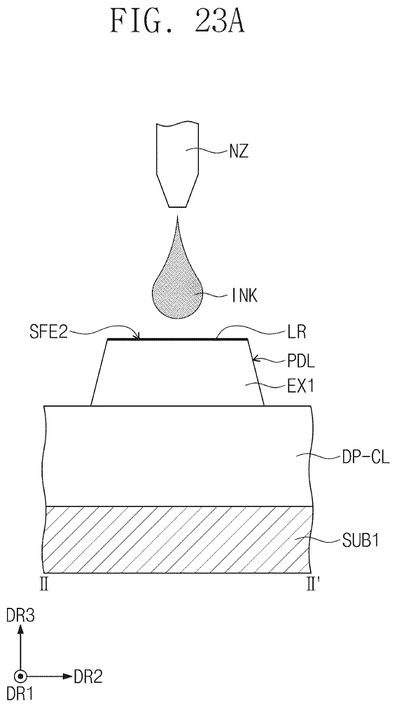

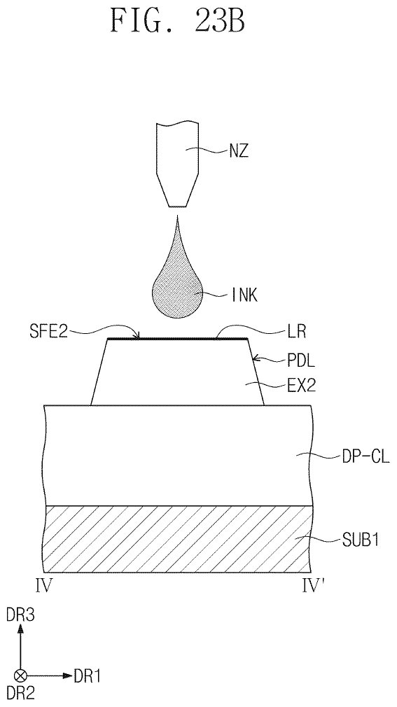

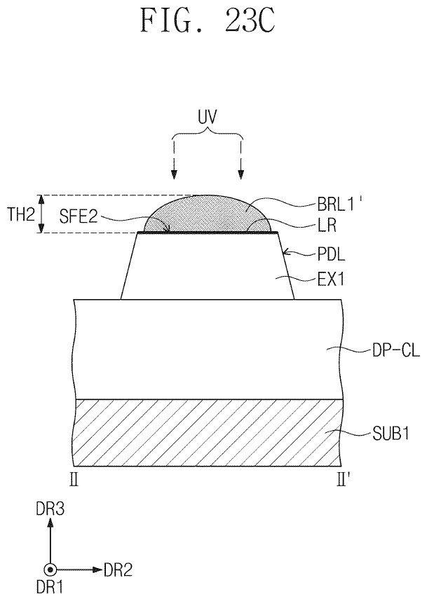

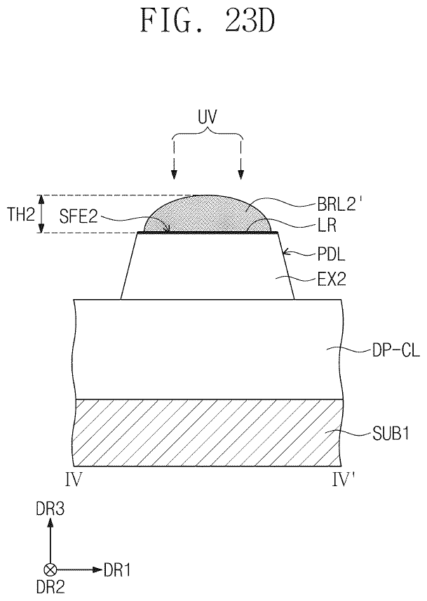

Hereinafter, in FIGS. 23A to 23D, FIG. 24, and FIGS. 25A to 25D, if (e.g., when) the pixel defining film PDL has the second surface energy, a method of forming the barrier layer BRL′ will be described later.

FIGS. 23A to 23D are views illustrating a method of forming the first and second barrier layers illustrated in the cross sections of FIGS. 14 and 16.

Referring to FIGS. 23A and 23B, the upper surface of the pixel defining film PDL may have second surface energy SFE2 greater than the first surface energy SFE1. The ink INK may be provided to the upper surfaces of the first and second extension portions EX1 and EX2 of the pixel defining film PDL through the nozzle NZ.

Referring to FIGS. 23C and 23D, the ink INK provided in the liquid-repellent layer LR may have a property of clumping together and thus may have an upwardly convex curved shape. If (e.g., when) the upper surface of the pixel defining film PDL has the second surface energy SFE2, the ink INK provided on the upper surface of the pixel defining film PDL may have the second thickness TH2 that is smaller than the first thickness TH1 in the third direction DR3. As the ink INK is cured, the first barrier layer BRL1′ may be formed on the first extension portion EX1, and the second barrier layer BRL2′ may be formed on the second extension portion EX2.

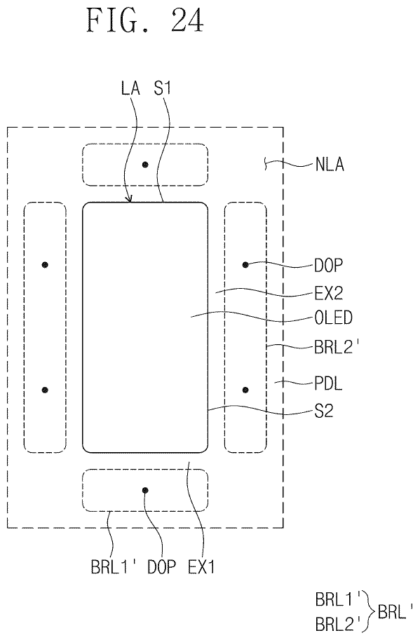

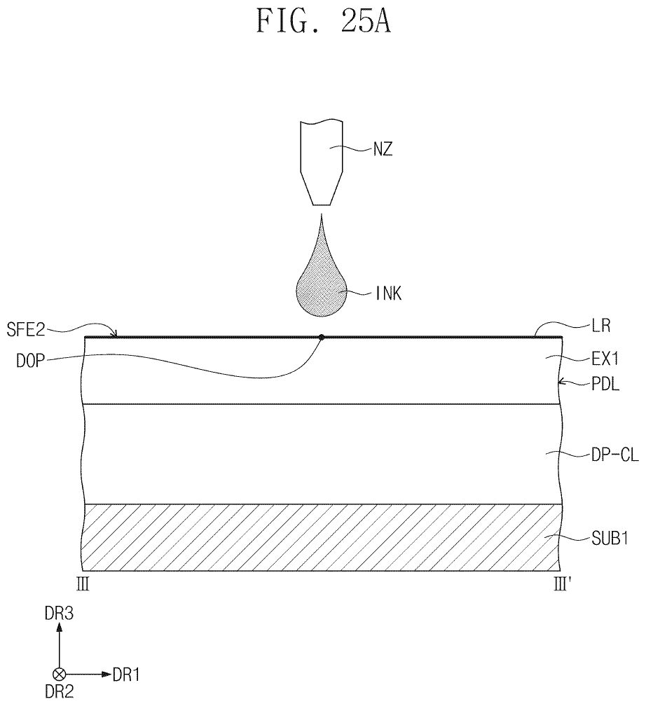

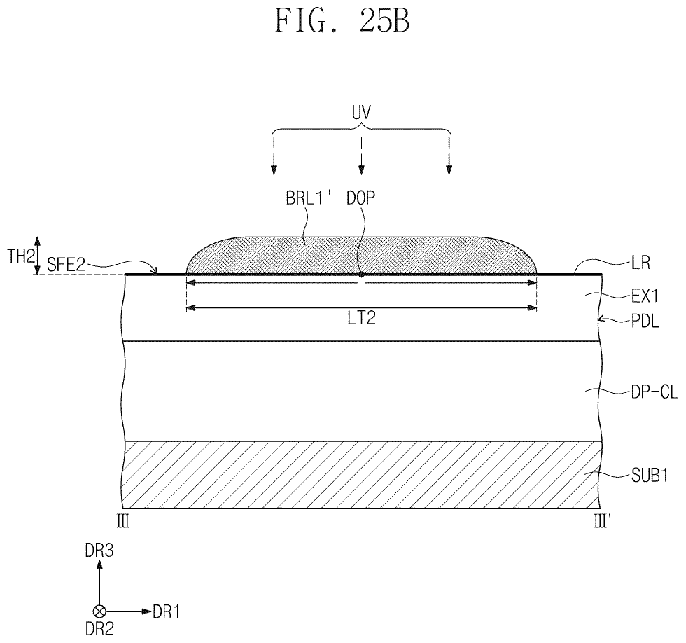

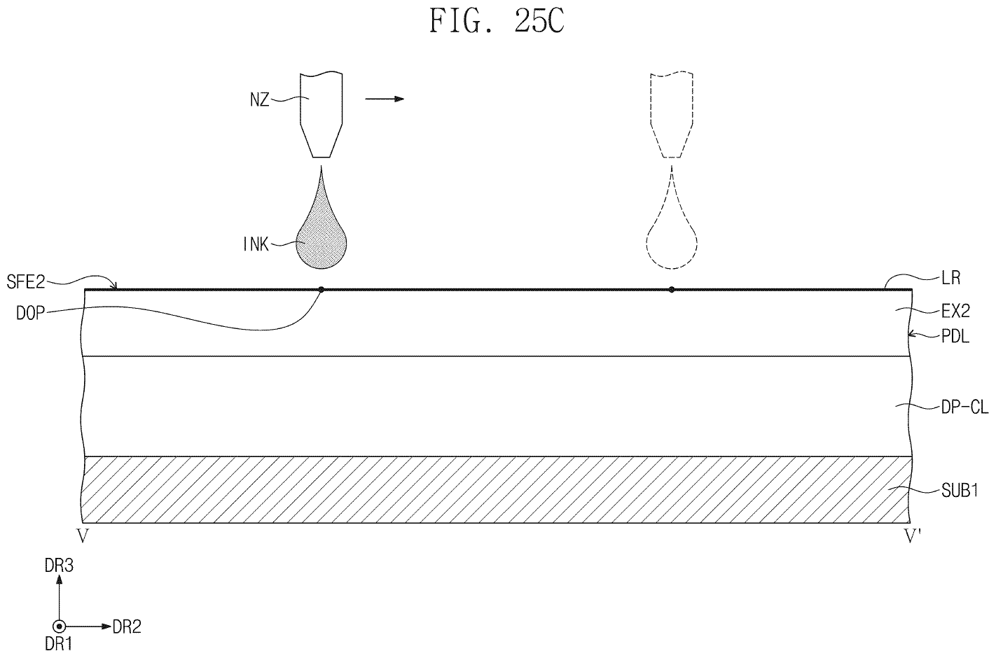

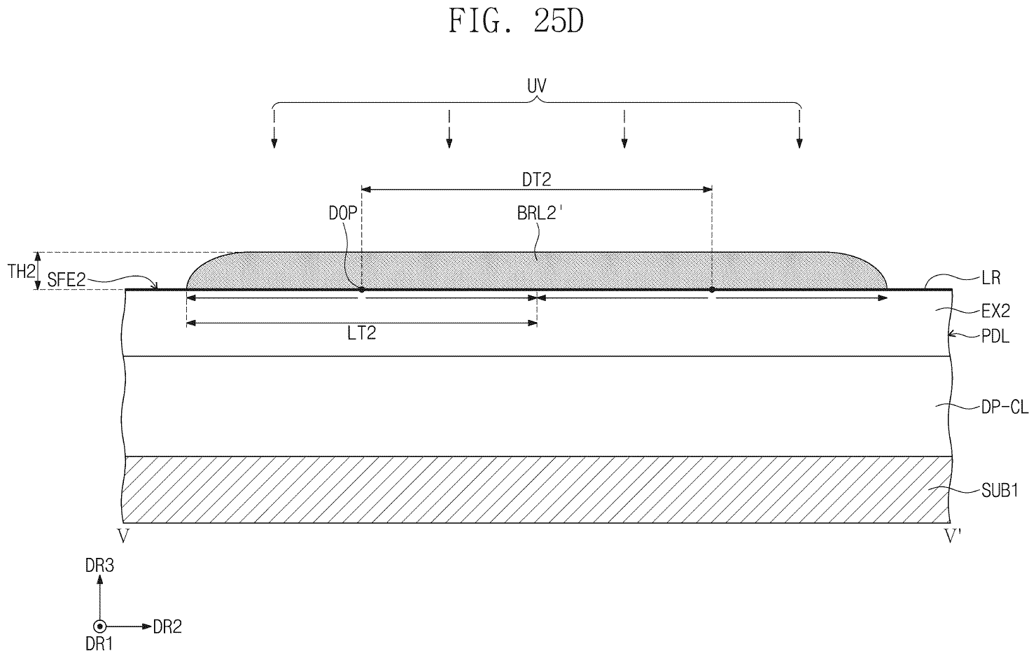

FIG. 24 is a view illustrating the plurality of drop points of ink in the method of manufacturing a display device if (e.g., when) the upper surface of the pixel defining film has second surface energy. FIGS. 25A to 25D are views for describing a method of forming the first and second barrier layers illustrated in the cross sections of FIGS. 15 and 17 if (e.g., when) the upper surface of the pixel defining film has the second surface energy.

FIG. 24 is illustrated as a plane (e.g., a plan view) corresponding to FIG. 21, and hereinafter, components illustrated in FIGS. 24 and 25A to 25D will be described while focused on components different from those illustrated in FIGS. 21 and 22A to 22D.

Referring to FIG. 24, the plurality of drop points DOP may be defined on the upper surface of the pixel defining film PDL, and the ink INK may be provided to the plurality of drop points DOP. The ink INK may be provided to the plurality of drop points DOP to form the first and second barrier layers BRL1′ and BRL2′.

In FIG. 24, the one drop point DOP may be defined on the upper surface of each of the first extension portions EX1, and the two drop points DOP may be defined on the upper surface of each of the second extension portions EX2. If (e.g., when) the pixel defining film PDL has the second surface energy SFE2 greater than the first surface energy SFE1, the number of drop points DOP defined on the upper surface of the pixel defining film PDL may be decreased.

Referring to FIGS. 24, 25A and 25B, the ink INK may be provided to the drop point DOP defined on the upper surface of the first extension portion EX1, and the ink INK may be cured to form the first barrier layer BRL1′ on the first extension portion EX1. At the drop point DOP on the first extension portion EX1, the spread length of the ink INK may be defined as a second length LT2.

Referring to FIGS. 24, 25C and 25D, the ink INK may be provided to each of the plurality of drop points DOP defined on the upper surface of the second extension portion EX2, and the ink INK may be cured to form the second barrier layer BRL2′ on the second extension portion EX2.

At each of the plurality of drop points DOP on the second extension portion EX2, the spread length of the ink INK along the second side S2 may be defined as the second length LT2. A distance between the plurality of drop points DOP adjacent to each other on the second extension portion EX2 may be defined as a second distance DT2. The second length LT2 may be greater than the first length LT1, and the second distance DT2 may be greater than the first distance DT1.

According to the above-described manufacturing method, if (e.g., when) the upper surface of the pixel defining film PDL has the second surface energy SFE2, the ink INK provided to each of the plurality of drop points DOP may be spread to have the second thickness TH2 and have the second length LT2. Furthermore, if (e.g., when) the upper surface of the pixel defining film PDL has the second surface energy SFE2, a distance between the plurality of drop points DOP adjacent to each other may be set to the second distance DT2.

If (e.g., when) the upper surface of the pixel defining film PDL has the second surface energy SFE2 greater than the first surface energy SFE1, the ink INK provided to each of the plurality of drop points DOP may be spread to have the second thickness TH2 smaller than the first thickness TH1 and have the second length LT2 greater than the first length LT1.

Furthermore, the second distance DT2 between the plurality of drop points DOP adjacent to each other if (e.g., when) the upper surface of the pixel defining film PDL has the second surface energy SFE2 may be greater than the first distance DT1 between the plurality of drop points DOP adjacent to each other if (e.g., when) the upper surface of the pixel defining film PDL has the first surface energy SFE1.

Referring to the above-described method of manufacturing the barrier layers BRL and BRL′, the thickness of the ink INK and the spread length of the ink INK provided to each of the plurality of drop points DOP may be changed according to the surface energy of the upper surface of the pixel defining film PDL. For example, as the surface energy of the pixel defining film PDL becomes greater (increases), the ink INK provided to each of the plurality of drop points DOP may have a smaller thickness and may be spread longer along the side of the light emitting area LA. Furthermore, as the surface energy of the upper surface of the pixel defining film PDL becomes greater (increases), the distance between the plurality of drop points DOP adjacent to each other may become greater (increase).

The method of manufacturing the barrier layers BRL and BRL′ if (e.g., when) the pixel defining film PDL has the first surface energy SFE1 and the second surface energy SFE2 has been described. However, the present disclosure is not limited thereto, and barrier layers having one or more suitable thicknesses may be formed by variously setting the surface energy of the upper surface of the pixel defining film PDL.

In other words, the method of manufacturing the barrier layers BRL and BRL′ involves adjusting the thickness and spread length of the ink (INK) at each drop point (DOP) based on the surface energy of the upper surface of the pixel defining film (PDL). As the surface energy of the PDL increases, the ink at each drop point becomes thinner and spreads further along the side of the light emitting area (LA). Additionally, higher surface energy results in greater distances between adjacent drop points. This method has been described for cases where the PDL has the first surface energy (SFE1) and the second surface energy (SFE2). However, the present disclosure is not limited to these conditions, and barrier layers with various suitable thicknesses can be formed by adjusting the surface energy of the PDL.

In one or more embodiments of the present disclosure, a photo process using a mask is not utilized to form the barrier layers BRL and BRL′, and the barrier layers BRL and BRL′ may be formed by an inkjet printing process of discharging the ink. Thus, an expensive mask is not utilized, and thus manufacturing costs may be decreased.

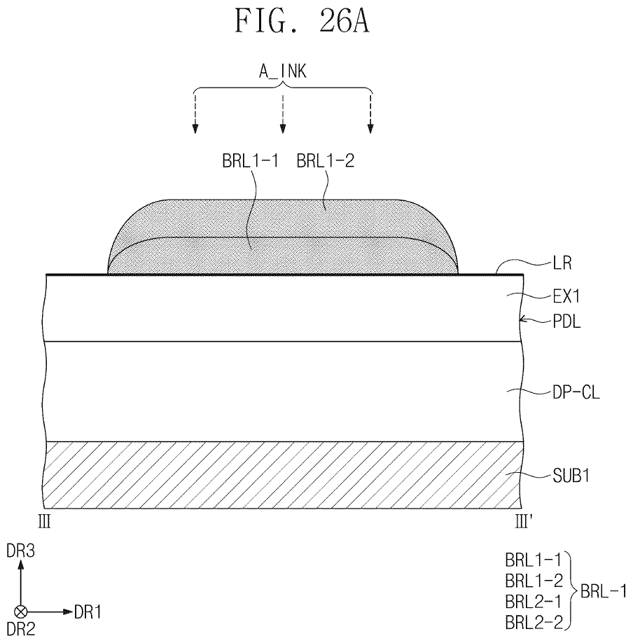

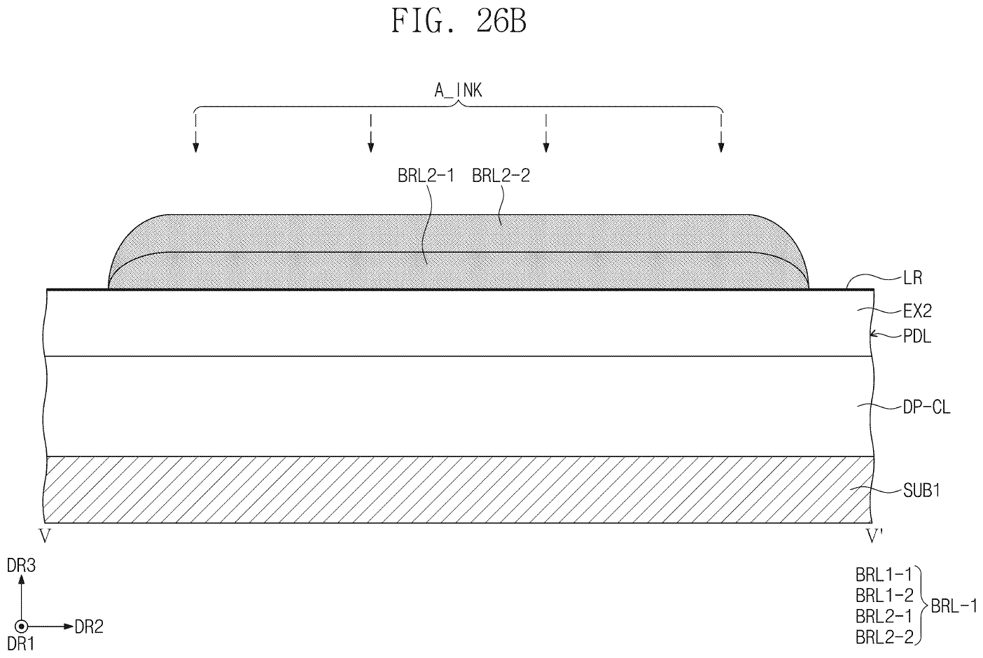

FIGS. 26A and 26B are views each illustrating a configuration of the barrier layer, according to one or more embodiments of the present disclosure.

FIGS. 26A and 26B are illustrated in the cross sections corresponding to FIGS. 9 and 11. Hereinafter, configurations of a barrier layer BRL-1 illustrated in FIGS. 26A and 26B will be described while focused on configurations different from those illustrated in FIGS. 9 and 11.

Referring to FIGS. 26A and 26B, the barrier layer BRL-1 may include a first barrier layer BRL1-1, a first dummy barrier layer BRL1-2, a second barrier layer BRL2-1, and/or a second dummy barrier layer BRL2-2. The first barrier layer BRL1-1 and the first dummy barrier layer BRL1-2 may be arranged on the first extension portion EX1. The second barrier layer BRL2-1 and the second dummy barrier layer BRL2-2 may be arranged on the second extension portion EX2.

The first barrier layer BRL1-1 may be arranged on the first extension portion EX1, and the first dummy barrier layer BRL1-2 may be arranged on the first barrier layer BRL1-1. The second barrier layer BRL2-1 may be arranged on the second extension portion EX2, and the second dummy barrier layer BRL2-2 may be arranged on the second barrier layer BRL2-1.

Additional ink A_INK may be provided onto the first barrier layer BRL1-1, and the additional ink A_INK may be cured to form the first dummy barrier layer BRL1-2. The additional ink A_INK may be provided onto the second barrier layer BRL2-1, and the additional ink A_INK may be cured to form the second dummy barrier layer BRL2-2.

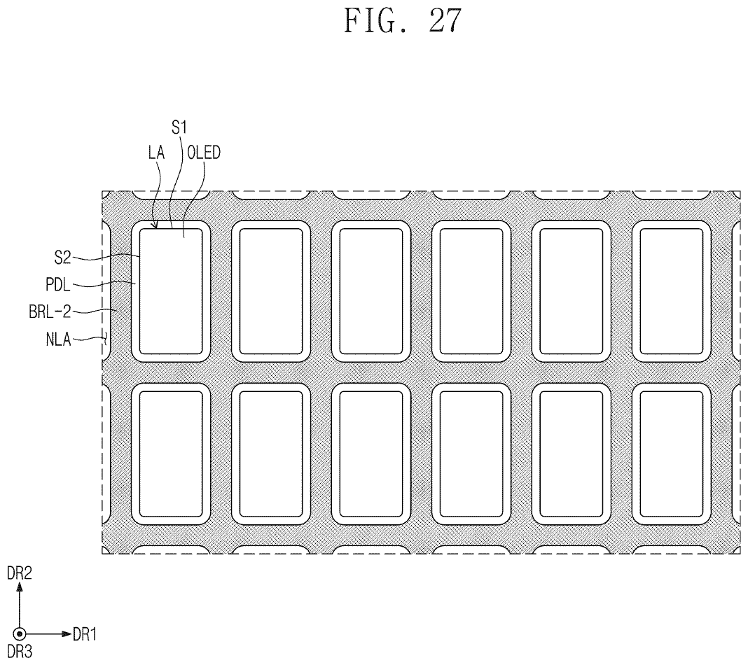

FIG. 27 is a view illustrating a configuration of the barrier layer according to one or more embodiments of the present disclosure.

FIG. 27 is illustrated in a plane (e.g., a plan view) corresponding to FIG. 6. Hereinafter, configurations of barrier layers BRL-2 illustrated in FIG. 27 will be described while focused on configurations different from those illustrated in FIG. 6.

Referring to FIG. 27, the barrier layer BRL-2 may be arranged to continuously be around (e.g., surround) each of the light emitting areas OLED. The barrier layer BRL-2 may have a grid shape to continuously be around (e.g., surround) the light emitting areas OLED. Referring to the above-described manufacturing method, the ink INK may be provided onto the pixel defining film PDL to continuously be around (e.g., surround) each of the light emitting areas OLED, thereby forming the barrier layer BRL-2.

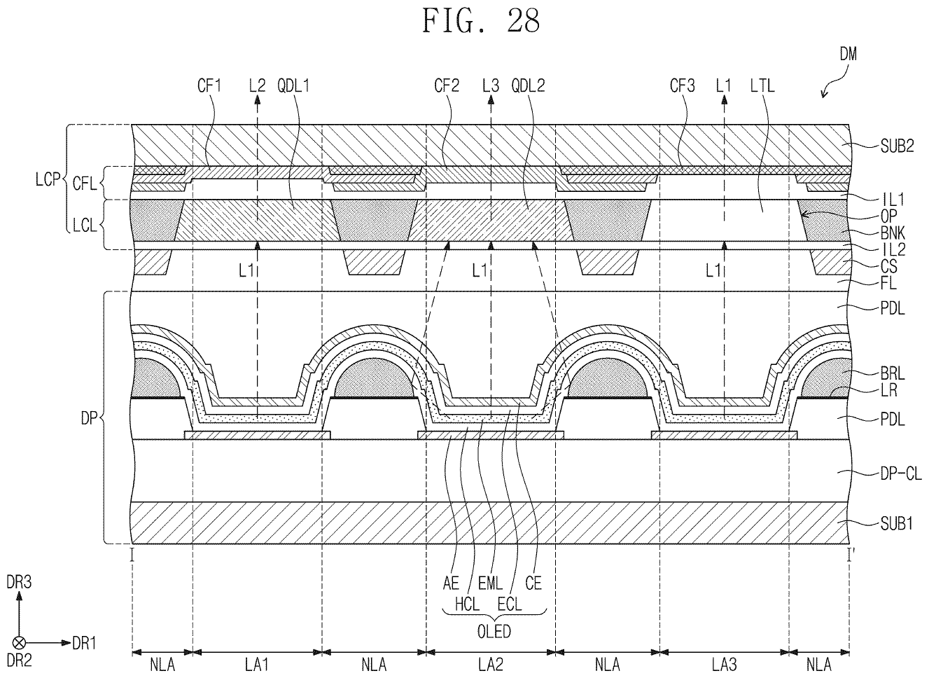

FIG. 28 is a view illustrating a configuration of the barrier layer according to one or more embodiments of the present disclosure.

FIG. 28 is illustrated in a cross section corresponding to FIG. 7. Hereinafter, configurations of barrier layers BRL-3 illustrated in FIG. 27 will be described while focused on configurations different from those illustrated in FIG. 7.

Referring to FIG. 28, the barrier layers BRL-3 may not have black color. The barrier layers BRL-3 may include a light-reflective material. For example, the barrier layers BRL-3 may include titanium dioxide (TiO₂) that may reflect a light.

The first light L1 traveling in the lateral direction from the light emitting elements OLED may be reflected by the barrier layers BRL-3 and travel upward. For example, the first light L1 traveling in the lateral direction from the light emitting element OLED overlapping the second light emitting area LA2 may be reflected by the barrier layers BRL-3 and provided to the second quantum dot layer QDL2, as indicated by a dotted arrow. Thus, light efficiency may be improved.

In other words, FIGS. 26A and 26B illustrate a configuration of the barrier layer BRL-1, which includes a first barrier layer BRL1-1, a first dummy barrier layer BRL1-2, a second barrier layer BRL2-1, and a second dummy barrier layer BRL2-2. The first barrier layer BRL1-1 and the first dummy barrier layer BRL1-2 are arranged on the first extension portion EX1, while the second barrier layer BRL2-1 and the second dummy barrier layer BRL2-2 are arranged on the second extension portion EX2. Additional ink (A_INK) is applied and cured to form the dummy barrier layers. FIG. 27 shows the barrier layer BRL-2, which surrounds each light emitting area OLED in a grid shape. The ink (INK) is applied to the pixel defining film (PDL) to form this barrier layer. FIG. 28 depicts the barrier layers BRL-3, which include a light-reflective material like titanium dioxide (TiO2) and do not have a black color. These barrier layers reflect the first light L1 traveling laterally from the OLEDs, directing it upward to improve light efficiency.

According to one or more embodiments of the present disclosure, a light generated by each of light emitting elements may be shielded by a barrier layer arranged on a pixel defining film, such that the light is prevented or reduced from being provided to another light converting layer adjacent to a corresponding light converting layer. Thus, a color matching rate of a display device may be improved.

Furthermore, to form the barrier layer, a photo process using a mask is not utilized, and the barrier layer may be formed by an inkjet printing process that discharges an ink. Thus, an expensive mask is not utilized, and thus manufacturing costs may be reduced.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display device, a device of manufacturing a display device, and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments has been described above, those skilled in the art may understand that the present disclosure may be variously modified and changed without departing from the spirit and scope of the present disclosure described in the appended claims. Further, it should be interpreted that one or more embodiments disclosed in the present disclosure is not intended to limit the technical spirit of the present disclosure and all technical spirits within the appended claims and equivalents thereto are included in the scope of the present disclosure.

What is claimed is:

1. A method of manufacturing a display device, method comprising:
providing a pixel defining film on a substrate;
defining an opening, overlapping a light emitting area, in the pixel defining film;
applying an ink to each of a plurality of drop points on an upper surface of the pixel defining film, overlapping a non-light emitting area around the light emitting area;
forming a barrier layer by curing the ink; and
placing a light emitting element in the opening.

2. The method of claim 1, wherein the pixel defining film comprises an extension portion adjacent to one side of the light emitting area and extending in one direction parallel to the one side of the light emitting area, and
wherein the ink is applied to at least one drop point in an upper surface of the extension portion.

3. The method of claim 1, wherein a thickness of the ink applied to each of the plurality of drop points and a spread length of the ink along a side of the light emitting area are changed depending on surface energy of the upper surface of the pixel defining film.

4. The method of claim 3, wherein the ink applied to each of the plurality of drop points has a smaller thickness and is spread further along the side of the light emitting area as the surface energy of the upper surface of the pixel defining film increases.

5. The method of claim 3, wherein, when the upper surface of the pixel defining film has first surface energy, the ink applied to each of the plurality of drop points has a first thickness and is spread to have a first length along the side of the light emitting area.

6. The method of claim 5, wherein, when the upper surface of the pixel defining film has second surface energy greater than the first surface energy, the ink applied to each of the plurality of drop points has a second thickness smaller than the first thickness and is spread to have a second length greater than the first length.

7. The method of claim 6, wherein the ink is applied to each of the plurality of drop points in the upper surface of the pixel defining film, and
wherein a distance between each of the plurality of drop points adjacent to each other when the upper surface of the pixel defining film has the second surface energy is greater than a first distance between each of the plurality of drop points adjacent to each other when the upper surface of the pixel defining film has the first surface energy.

8. The method of claim 1, wherein the light emitting area comprises:
a first side extending in a first direction; and
a second side extending in a second direction crossing the first direction and being longer than the first side,
wherein the pixel defining film comprises:
a first extension portion being adjacent to the first side and extending in the first direction; and
a second extension portion being adjacent to the second side, extending in the second direction, and being longer than the first extension portion,
wherein the barrier layer comprises:
a first barrier layer on the first extension portion and extending in the first direction; and
a second barrier layer separated from the first barrier layer, on the second extension portion, extending in the second direction, and being longer than the first barrier layer, and
wherein the drop points are more in the second extension portion than in the first extension portion.

9. The method of claim 1, further comprising:
forming the upper surface of the pixel defining film with a liquid-repellent layer.

10. The method of claim 1, wherein a cross section of the barrier layer cut in a direction crossing an extension direction of the barrier layer has an upwardly convex curved surface.

11. The method of claim 1, wherein the barrier layer is black in color.

12. The method of claim 1, further comprising:
applying an additional ink onto the barrier layer; and
forming a dummy barrier layer on the barrier layer by curing the additional ink.

13. The method of claim 1, wherein the ink is applied onto the upper surface of the pixel defining film to continuously surround the light emitting area.

14. The method of claim 1, wherein the barrier layer comprises light-reflective material.

15. A display device comprising:
a substrate comprising a light emitting area and a non-light emitting area around the light emitting area;
a pixel defining film which is on the substrate, in which an opening overlapping the light emitting area is defined, and which overlaps the non-light emitting area;
a barrier layer on the pixel defining film; and
a light emitting element in the opening,
wherein an upper surface of the pixel defining film has liquid repellency, and a cross section of the barrier layer cut in a direction crossing an extension direction of the barrier layer has an upwardly convex curved surface.

16. The display device of claim 15, wherein the light emitting area comprises:
a first side extending in a first direction; and
a second side extending in a second direction crossing the first direction,
wherein the pixel defining film comprises:
a first extension portion being adjacent to the first side and extending in the first direction; and
a second extension portion being adjacent to the second side and extending in the second direction, and
wherein the barrier layer comprises:
a first barrier layer on the first extension portion and extending in the first direction; and
a second barrier layer separated from the first barrier layer, on the second extension portion, and extending in the second direction.

17. The display device of claim 15, wherein the barrier layer is black in color.

18. The display device of claim 15, wherein the barrier layer continuously surrounds the light emitting area.

19. The display device of claim 15, wherein the barrier layer comprises a light-reflective material.

20. A method of manufacturing a display device, the method comprising:
providing a pixel defining film on a substrate;
defining an opening, overlapping a light emitting area, in the pixel defining film;
applying an ink to each of a plurality of drop points on an upper surface of the pixel defining film overlapping a non-light emitting area around the light emitting area;
forming a barrier layer by curing the ink;
placing a light emitting element in the opening; and
providing a quantum dot layer on the light emitting element,
wherein the ink applied to each of the plurality of drop points has a smaller thickness and is spread further along a side of the light emitting area as surface energy of the upper surface of the pixel defining film increases.
